(19) United States
(12) Patent Application Publication
(10) Pub. No.: US 2024/0332910 A1
(43) Pub. Date: Oct. 3, 2024

(54) HIGH-EFFICIENCY ACTIVE LAYER AND SEMICONDUCTOR LIGHT-EMITTING DEVICE AND PREPARATION METHOD

(71) Applicants: SUZHOU EVERBRIGHT PHOTONICS CO., LTD., Suzhou, Jiangsu (CN); EVERBRIGHT INSTITUTE OF SEMICONDUCTOR PHOTONICS CO., LTD., Suzhou, Jiangsu (CN)

(72) Inventors: Jun WANG, Suzhou (CN); Shaoyang TAN, Suzhou (CN); Li ZHOU, Suzhou (CN); Yang CHENG, Suzhou (CN); Xiao XIAO, Suzhou (CN); Yintao GUO, Suzhou (CN); Hao YU, Suzhou (CN); Quanling LI, Suzhou (CN); Xinsheng LIAO, Suzhou (CN); Dayong MIN, Suzhou (CN)

(73) Assignees: SUZHOU EVERBRIGHT PHOTONICS CO., LTD., Suzhou, Jiangsu (CN); EVERBRIGHT INSTITUTE OF SEMICONDUCTOR PHOTONICS CO., LTD., Suzhou, Jiangsu (CN)

(21) Appl. No.: 18/572,689

(22) PCT Filed: May 29, 2023
(86) PCT No.: PCT/CN2023/096810

§ 371 Date: Dec. 20, 2023

(30) Foreign Application Priority Data
Apr. 6, 2022 (CN) 202210353728.7

(51) Int. Cl. H01S 5/34; H01S 5/343

(52) U.S. Cl. CPC H01S 5/3403; H01S 5/3407; H01S 5/3434; H01S 5/34353; H01S 5/3436

(57) ABSTRACT

A high-efficiency active layer includes a strained quantum well layer and, at one side thereof, a first strained barrier layer configured to transport electrons. The first strained barrier layer and the strained quantum well layers are configured to form strain compensation. A second barrier layer is positioned on the other side of the strained quantum well layer and is configured to transport holes. A band offset between conduction bands of the first strained barrier layer and of the strained quantum well layer is less than a band offset between valence bands of the strained quantum well layer and of the first strained barrier layer. A band offset between valence bands of the strained quantum well layer and of the second barrier layer is less than a band offset between conduction bands of the second barrier layer and of the strained quantum well layer. Light-emitting efficiency and reliability are improved.

### CROSS REFERENCE TO RELATED APPLICATIONS

The present application claims the priority of the Chinese patent application filed with the Chinese Patent Office on Apr. 6, 2022, with an application number of CN202210353728.7 and entitled “High-Efficiency Active Layer and Semiconductor Light-emitting Device and Preparation Method”, the contents of which are incorporated herein by reference in its entirety.

### TECHNICAL FIELD

The present application relates to the technical field of semiconductors, in particular to a high-efficiency active layer and a semiconductor light-emitting device and a manufacturing method.

### BACKGROUND ART

Semiconductor light-emitting structures are devices that use a certain semiconductor material as a working material to generate a stimulated emission effect. The working principle is to achieve population inversion of nonequilibrium carriers between energy bands (conduction bands and valence bands) of the semiconductor material, or between energy bands of the semiconductor material and impurity (acceptors or donors) energy levels through a certain excitation method.

When a large number of electrons in a population inversion state are recombined with holes, a stimulated emission effect is generated, and semiconductor light-emitting structures are widely used due to their small size and high electro-optical conversion efficiency.

The light-emitting efficiency and reliability of the existing semiconductor light-emitting structure and active layer need to be further improved.

### SUMMARY OF THE INVENTION

Therefore, an object of the present application is to provide a high-efficiency active layer and a semiconductor light-emitting device and a manufacturing method, to overcome the problem that the light-emitting efficiency and reliability of the active layer and the semiconductor light-emitting structure in the prior art need to be further improved.

The present application provides a high-efficiency active layer, including: a strained quantum well layer; a first strained barrier layer located on one side of the strained quantum well layer, wherein the first strained barrier layer is configured to transport electrons; and the first strained barrier layer and the strained quantum well layer are configured to form strain compensation; a second barrier layer located on the other side of the strained quantum well layer, wherein the second barrier layer is configured to transport holes; wherein a band offset between a conduction band of the first strained barrier layer and a conduction band of the strained quantum well layer is less than a band offset between a valence band of the strained quantum well layer and a valence band of the first strained barrier layer, and a band offset between a valence band of the strained quantum well layer and a valence band of the second barrier layer is less than a band offset between a conduction band of the second barrier layer and a conduction band of the strained quantum well layer.

Optionally, the band offset between the conduction band of the first strained barrier layer and the conduction band of the strained quantum well layer is less than the band offset between the conduction band of the second barrier layer and the conduction band of the strained quantum well layer; and a band offset between the valence band of the strained quantum well layer and the valence band of the second barrier layer is less than the band offset between the valence band of the strained quantum well layer and the valence band of the first strained barrier layer.

Optionally, a band gap of the first strained barrier layer is equal to a band gap of the second barrier layer.

Optionally, a luminous wavelength of the high-efficiency active layer is in a range of 750 nm to 860 nm; and the strained quantum well layer is a tensile strained quantum well layer, and the first strained barrier layer is a compressive strained barrier layer; the material of the tensile strained quantum well layer includes GaAsₓ₃P₁₋ₓ₃; the material of the compressive strained barrier layer includes Inₓ₁Ga₁₋ₓ₁P; and the material of the second barrier layer includes Alₓ₂Ga₁₋ₓ₂As.

Optionally, a band offset between a conduction band of the compressive strained barrier layer and a conduction band of the tensile strained quantum well layer is a first band offset; a band offset between a valence band of the tensile strained quantum well layer and a valence band of the compressive strained barrier layer is a second band offset; and a ratio of the first band offset to the second band offset is in a range of 35/65 to 47/53.

Optionally, a band offset between the valence band of the tensile strained quantum well layer and the valence band of the second barrier layer is a third band offset; the band offset between the conduction band of the second barrier layer and the conduction band of the tensile strained quantum well layer is a fourth band offset; and a ratio of the third band offset to the fourth band offset is in a range of 35/65 to 47/53.

Optionally, the thickness of the tensile strained quantum well layer is in a range of 8 nm to 20 nm.

Optionally, x3 ranges from 0.70 to 0.95.

Optionally, the material of the tensile strained quantum well layer is GaAs_{0.82}P_{0.18}.

Optionally, a luminous wavelength of the high-efficiency active layer is in a range of 870 nm to 1100 nm; and the strained quantum well layer is a compressive strained quantum well layer, and the first strained barrier layer is a tensile strained barrier layer; the material of the compressive strained quantum well layer includes Inₓ₆Ga₁₋ₓ₆As; the material of the tensile strained barrier layer includes GaAsₓ₄P₁₋ₓ₄; and the material of the second barrier layer includes Alₓ₅Ga₁₋ₓ₅As.

Optionally, a band offset between a conduction band of the tensile strained barrier layer and a conduction band of the compressive strained quantum well layer is a first band offset; a band offset between a valence band of the compressive strained quantum well layer and a valence band of the tensile strained barrier layer is a second band offset; and a ratio of the first band offset to the second band offset is in a range of 30/70 to 45/55.

Optionally, the band offset between the valence band of the compressive strained quantum well layer and the valence band of the second barrier layer is a third band offset; the band offset between the conduction band of the second barrier layer and the conduction band of the compressive strained quantum well layer is a fourth band offset; and a ratio of the third band offset to the fourth band offset is in a range of 30/70 to 45/55.

Optionally, the thickness of the compressive strained quantum well layer is in a range of 4 nm to 8 nm.

Optionally, the material of the compressive strained quantum well layer has a compressive strain range of 0.1% to 2%.

Optionally, the material of the tensile strained barrier layer has a tensile strain range of 0.1% to 2%.

Optionally, x4 ranges from 0.7 to 0.95; x5 ranges from 0.05 to 0.3; and x6 ranges from 0.1 to 0.3.

The present application further provides a semiconductor light-emitting device, including the high-efficiency active layer of the present application.

Optionally, the semiconductor light-emitting device further includes a semiconductor substrate layer, wherein the high-efficiency active layer is located on the semiconductor substrate layer; and the material of the strained quantum well layer is tensilely strained relative to the material of the semiconductor substrate layer, and the material of the first strained barrier layer is compressively strained relative to the material of the semiconductor substrate layer; or, alternatively, the material of the strained quantum well layer is compressively strained relative to the material of the semiconductor substrate layer, and the material of the first strained barrier layer is tensilely strained relative to the material of the semiconductor substrate layer.

Optionally, the semiconductor light-emitting device further includes an N-type waveguide layer and a P-type waveguide layer arranged opposite to each other, wherein the high-efficiency active layer is located between the N-type waveguide layer and the P-type waveguide layer; and the semiconductor light-emitting device further includes an N-type limiting layer and a P-type limiting layer, wherein the N-type limiting layer is located on a side, away from the high-efficiency active layer, of the N-type waveguide layer, and the P-type limiting layer is located on a side, away from the high-efficiency active layer, of the P-type waveguide layer.

The present application further provides a method for manufacturing the high-efficiency active layer, including: forming a first strained barrier layer, wherein the first strained barrier layer is configured to transport electrons; forming a second barrier layer, wherein the second barrier layer is configured to transport holes; and forming a strained quantum well layer between the step of forming the first strained barrier layer and the step of forming the second barrier layer, wherein the first strained barrier layer and the strained quantum well layer are configured to form strain compensation; wherein the band offset between the conduction band of the first strained barrier layer and the conduction band of the strained quantum well layer is less than the band offset between the valence band of the strained quantum well layer and the valence band of the first strained barrier layer, and the band offset between the valence band of the strained quantum well layer and the valence band of the second barrier layer is less than a band offset between the conduction band of the second barrier layer and the conduction band of the strained quantum well layer.

Optionally, a luminous wavelength of the high-efficiency active layer is in a range of 750 nm to 860 nm; the strained quantum well layer is a tensile strained quantum well layer, and the first strained barrier layer is a compressive strained barrier layer; the material of the tensile strained quantum well layer includes GaAsₓ₃P₁₋ₓ₃; the material of the compressive strained barrier layer includes Inₓ₁Ga₁₋ₓ₁P; and the material of the second barrier layer includes Alₓ₂Ga₁₋ₓ₂As.

Optionally, the strained quantum well layer is formed after the first strained barrier layer is formed; in the step of forming the first strained barrier layer, the In-source gas, the Ga-source gas and the P-source gas are introduced; in the step of forming the strained quantum well layer, the Gas-source gas, the As-source gas and the P-source gas are introduced; and between the step of forming the first strained barrier layer and the step of forming the strained quantum well layer, first interruption processing, second interruption processing and third interruption processing are sequentially performed; during the first interruption processing, the In-source gas, the Ga-source gas and the As-source gas are turned off, and the P-source gas is introduced; during the second interruption processing, the In-source gas and the Ga-source gas are turned off, and the As-source gas and the P-source gas are introduced; and during the third interruption processing, the In-source gas and the Ga-source gas are turned off, and the As-source gas and the P-source gas are introduced, and a supplying amount of the P-source gas decreases with time during the third interruption processing.

Optionally, the second barrier layer is formed after the strained quantum well layer is formed; in the step of forming the strained quantum well layer, the Ga-source gas, an As-source gas and the P-source gas are introduced; in the step of forming the second barrier layer, an Al-source gas, the Ga-source gas and the As-source gas are introduced; and fourth interruption processing is performed between the step of forming the strained quantum well layer and the step of forming the second barrier layer; and in the fourth interruption processing, the Ga-source gas and the P-source gas are turned off, and the As-source gas is introduced.

Optionally, a luminous wavelength of the high-efficiency active layer is in a range of 870 nm to 1100 nm; the strained quantum well layer is a compressive strained quantum well layer, and the first strained barrier layer is a tensile strained barrier layer; the material of the compressive strained quantum well layer includes Inₓ₆Ga₁₋ₓ₆As; the material of the tensile strained barrier layer includes GaAsₓ₄P₁₋ₓ₄; and the material of the second barrier layer includes Alₓ₅Ga₁₋ₓ₅As.

Optionally, the strained quantum well layer is formed after the first strained barrier layer is formed; in the step of forming the first strained barrier layer, a Ga-source gas, an As-source gas and a P-source gas are introduced; in the step of forming the strained quantum well layer, an In-source gas, the Ga-source gas and the As-source gas are introduced; and between the step of forming the first strained barrier layer and the step of forming the strained quantum well layer, first interruption processing and second interruption processing are sequentially performed; during the first interruption processing, the Ga-source gas is turned off and the As-source gas and the P-source gas are introduced; and during the second interruption processing, the Ga-source gas is turned off, and the As-source gas and the P-source gas are introduced, a supplying amount of the P-source gas decreases with time during the second interruption processing, while a supplying amount of the As-source gas increases with time during the second interruption processing.

Optionally, the growth temperature for forming the strained quantum well layer is lower than the growth temperature for forming the first strained barrier layer and is lower than the temperature during the first interruption processing; the growth temperature for forming the strained quantum well layer is constant during the step of forming the strained quantum well layer, the growth temperature for forming the first strained barrier layer is constant during the step of forming the first strained barrier layer, and the temperature during the first interruption processing is constant; the temperature during the second interruption processing is high than the growth temperature for forming the strained quantum well layer and is lower than the temperature during the first interruption processing, and the temperature during the second interruption processing decreases with time.

Optionally, the second barrier layer is formed after the strained quantum well layer is formed; in the step of forming the strained quantum well layer, the In-source gas, the Ga-source gas and the As-source gas are introduced; in the step of forming the second barrier layer, an Al-source gas, the Ga-source gas and the As-source gas are introduced; and third interruption processing is performed between the step of forming the strained quantum well layer and the step of forming the second barrier layer; and during the third interruption processing, the In-source gas and the Ga-source gas are turned off, and the As-source gas is introduced.

Optionally, the growth temperature for forming the strained quantum well layer is lower than the growth temperature for forming the second barrier layer; the growth temperature for forming the strained quantum well layer is constant during the step of forming the strained quantum well layer, and the growth temperature for forming the second barrier layer is constant during the step of forming the second barrier layer; the temperature during the third interruption processing is greater than greater than the growth temperature for forming the strained quantum well layer and is lower than the growth temperature for forming the second barrier layer, and the temperature during the third interruption processing increases with time.

The present application further provides a method for manufacturing a semiconductor light-emitting device, including a method for manufacturing the high-efficiency active layer of the present application.

Optionally, the method for manufacturing the semiconductor light-emitting device further includes: providing a semiconductor substrate layer; wherein the step of forming the first strained barrier layer is performed by forming the first strained barrier layer on the semiconductor substrate layer; and the step of forming the second barrier layer is performed by forming the second barrier layer on the semiconductor substrate layer; and the material of the strained quantum well layer is tensilely strained relative to the material of the semiconductor substrate layer, and the material of the first strained barrier layer is compressively strained relative to the material of the semiconductor substrate layer; or, alternatively, the material of the strained quantum well layer is compressively strained relative to the material of the semiconductor substrate layer, and the material of the first strained barrier layer is tensilely strained relative to the material of the semiconductor substrate layer.

Technical solutions of the present application have the following beneficial effects:

as to the high-efficiency active layer provided in the technical solutions of the present application, a band offset between a conduction band of a first strained barrier layer and a conduction band of a strained quantum well layer is less than a band offset between a valence band of the strained quantum well layer and a valence band of the first strained barrier layer. A band offset between the valence band of the strained quantum well layer and the valence band of the second barrier layer is less than the band offset between the conduction band of the second barrier layer and the conduction band of the strained quantum well layer. Due to a smaller band offset between the conduction band of the first strained barrier layer and the conduction band of the strained quantum well layer, the barrier of the first strained barrier layer to electrons is reduced, therefore, the ability of conducting electrons in the first strained barrier layer is better, and more electrons can be transferred to the strained quantum well layer. Due to a larger band offset between the valence band of the strained quantum well layer and the valence band of the first strained barrier layer, the first strained barrier layer can block the conduction of holes from the strained quantum well layer to the first strained barrier layer, and suppress hole leakage, and more holes can be located in the strained quantum well layer, thereby enhancing the recombination efficiency of holes and electrons and improving the light-emitting efficiency. Due to the smaller band offset between the valence band of the strained quantum well layer and the valence band of the second barrier layer, the barrier of the second barrier layer to holes is reduced, therefore, the ability of conducting holes in the second barrier layer is better, and more holes can be transferred to the strained quantum well layer. The band offset between the conduction band of the second barrier layer and the conduction band of the strained quantum well layer is large, so the second barrier layer can block the conduction of electrons from the strained quantum well layer to the second barrier layer, and suppress electron leakage, and more electrons can be located in the strained quantum well layer, thereby enhancing the recombination efficiency of holes and electrons and improving the light-emitting efficiency. Secondly, the strained quantum well layer is strained, such that a light hole valence band is separated from the heavy hole valence band of the strained quantum well layer, the light hole valence band of the strained quantum well layer or the heavy hole valence band of the strained quantum well layer serve as a top layer of the valence band for energy level conversion. Through such a structural design, a gain effect of the strained quantum well layer is enhanced, and the state density of the valence band of the strained quantum well layer participating in light lasing is smaller, therefore, when the energy level difference between the two is larger, a higher gain effect is obtained, and the light-emitting efficiency is improved. In addition, the first strained barrier layer and strained quantum well layer form strain compensation, thereby being conducive to increasing long-term stability of the strained quantum well layer and improving reliability.

Further, the strained quantum well layer is a tensile strained quantum well layer, such that the light hole valence band is separated from the heavy hole valence band of the valence band of the tensile strained quantum well layer. The light hole valence band of the tensile strained quantum well layer is close to the conduction band of the tensile strained quantum well layer relative to the heavy hole valence band of the tensile strained quantum well layer, and the light hole valence band of the tensile strained quantum well layer serves as a top layer of the valence band for energy level conversion. Through such a structural design, a gain effect of the tensile strained quantum well layer is enhanced, and the state density of the valence band of the tensile strained quantum well layer participating in light lasing is smaller, therefore, when the energy level difference between the two is larger, a higher gain effect is obtained, and the light-emitting efficiency is improved. In addition, the first strained barrier layer is a compressive strained barrier layer, and the compressive strained barrier layer and the tensile strained quantum well layer form strain compensation, thereby being conducive to enhancing the gain effect of the tensile strained quantum well layer, enhancing long-term stability of the tensile strained quantum well layer and improving reliability. The material of the tensile strained quantum well layer includes GaAsₓ₃P₁₋ₓ₃, no Al element is available in the tensile strained quantum well layer, thereby improving reliability of the tensile strained quantum well layer. Thirdly, a smaller band offset between the conduction bands of the compressive strained barrier layer and the tensile strained quantum well layer and a smaller band offset between the valence bands of the tensile strained quantum well layer and the second barrier layer can be obtained simultaneously, and the turn-on voltage of a PN junction can be reduced.

Further, the strained quantum well layer is a compressive strained quantum well layer, such that the light hole valence band is separated from the heavy hole valence band of the valence band of the compressive strained quantum well layer. The heavy hole valence band of the compressive strained quantum well layer is close to the conduction band of the compressive strained quantum well layer relative to the light hole valence band of the compressive strained quantum well layer, and the heavy hole valence band of the compressive strained quantum well layer serves as a top layer of the valence band for energy level conversion. Through such a structural design, a gain effect of the compressive strained quantum well layer is enhanced, and the state density of the valence band of the compressive strained quantum well layer participating in light lasing is smaller, therefore, when the energy level difference between the two is larger, a higher gain effect is obtained, and the light-emitting efficiency is improved. In addition, the first strained barrier layer is a tensile strained barrier layer, and the tensile strained barrier layer and the compressive strained quantum well layer form strain compensation, thereby being conducive to enhancing the gain effect of the strained quantum well layer, enhancing long-term stability of the compressive strained quantum well layer and improving reliability. Next, the material of the compressive strained quantum well layer includes Inₓ₆Ga₁₋ₓ₆As, no Al element is available in the compressive strained quantum well layer, thereby improving reliability of the compressive strained quantum well layer. Secondly, a smaller band offset between the conduction bands of the tensile strained barrier layer and the compressive strained quantum well layer and a smaller band offset between the valence bands of the compressive strained quantum well layer and the second barrier layer can be obtained simultaneously, and the turn-on voltage of a PN junction can be reduced.

The semiconductor light-emitting device provided in the present application includes the high-efficiency active layer of the present application, and the light-emitting efficiency and reliability of the semiconductor light-emitting device are improved.

### BRIEF DESCRIPTION OF THE DRAWINGS

In order to more clearly illustrate specific embodiments of the present application or technical solutions in the prior art, a brief introduction will be given to the accompanying drawings which need to be used in the specific embodiments or description of the prior art. Apparently, the accompanying drawings in the following description are some embodiments of the present application. For those skilled in the art, other accompanying drawings can be obtained based on these drawings without any creative effort.

FIG. 1 is a structural schematic diagram of a high-efficiency active layer in Embodiment 1;

FIG. 2 is an energy band diagram of a high-efficiency active layer in Embodiment 1;

FIG. 3 is a schematic diagram of a barrier quasi-fermi level in a high-efficiency active layer in Embodiment 1;

FIG. 4 is an energy band diagram of an active layer in Comparative Example 1;

FIG. 5 is an energy band diagram of an active layer in Comparative Example 2;

FIG. 6 is a diagram showing the relationship between the thickness of the tensile strained quantum well layer and the difference between the conduction band energy level and the light hole valence band energy level of the tensile stress quantum well layer and the relationship between the thickness of the tensile strained quantum well layer and the difference between the conduction band energy level and the heavy hole valence band energy level of the tensile strained quantum well layer when the high-efficiency active layer with a light-emitting wavelength of 750 nm to 860 nm in Embodiment 2 corresponds to the tensile strained quantum well layers of different thickness;

FIG. 7 is a schematic diagram of the barrier quasi-fermi level in an active layer in Comparative Example 1;

FIG. 8 is a schematic diagram of the barrier quasi-fermi level in an active layer in Comparative Example 2;

FIG. 9 is an energy band diagram of an active layer in Comparative Example 3;

FIG. 10 is an energy band diagram of an active layer in Comparative Example 4;

FIG. 11 is a schematic diagram of the barrier quasi-fermi level in an active layer in Comparative Example 3;

FIG. 12 is a schematic diagram of the barrier quasi-fermi level in an active layer in Comparative Example 4;

FIG. 13 is a structural schematic diagram of a semiconductor light-emitting device in Embodiment 4;

FIG. 14 is an energy band diagram of a semiconductor light-emitting device in Embodiment 4;

FIG. 15 is an electron concentration distribution diagram in the semiconductor light-emitting device in Embodiment 6 and the semiconductor light-emitting structure in Comparative Example 6; and

FIG. 16 is a hole concentration distribution diagram in the semiconductor light-emitting device in Embodiment 5 and the semiconductor light-emitting structure in Comparative Example 5.

### DETAILED DESCRIPTION OF THE EMBODIMENTS

The technical solutions of the present application will be described clearly and completely below in combination with the accompanying drawings. Obviously, the described embodiments are a part but not all of the embodiments of the present application. Based on the embodiments in the present application, all the other embodiments obtained by those skilled in the art without any creative effort shall all fall within the protection scope of the present application.

In the description of the present application, it should be noted that the orientation or positional relationship indicated by such terms as “center”, “upper”, “lower”, “left”, “right”, “vertical”, “horizontal”, “inner”, “outer” and the like is the orientation or positional relationship based on the accompanying drawings. Such terms are merely for the convenience of description of the present application and simplified description, rather than indicating or implying that the device or element referred to must be located in a certain orientation or must be constructed or operated in a certain orientation, therefore, the terms cannot be understood as a limitation to the present application. In addition, the terms “first”, “second”, and “third” are merely for the purpose of description and cannot be understood as indicating or implying relative importance.

In addition, the technical features involved in different embodiments of the present application described below can be combined with each other as long as they do not conflict with each other.

### Embodiment 1

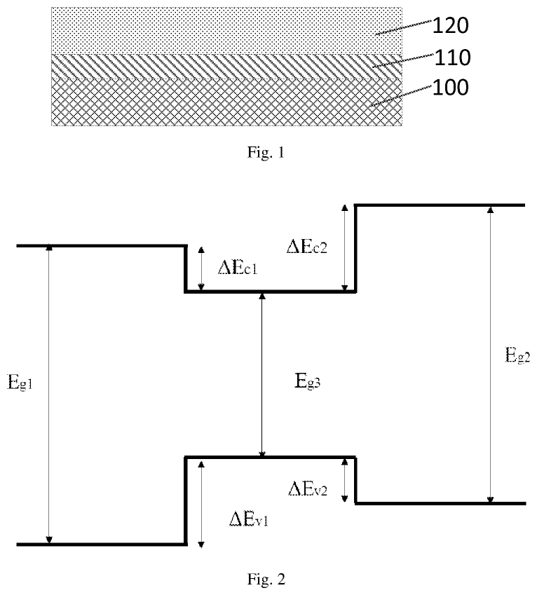

One embodiment of the present application provides a high-efficiency active layer, please refer to FIG. 1, the high-efficiency active layer includes:

a strained quantum well layer 110;

a first strained barrier layer 100 located on one side of the strained quantum well layer 110, wherein the first strained barrier layer 100 is configured to transport electrons; and the first strained barrier layer 100 and the strained quantum well layer 110 are configured to form strain compensation;

a second barrier layer 120 located on the other side of the strained quantum well layer 110, wherein the second barrier layer 120 is configured to transport holes; and

a band offset between a conduction band of the first strained barrier layer 100 and a conduction band of the strained quantum well layer 110 is less than a band offset between a valence band of the strained quantum well layer 110 and a valence band of the first strained barrier layer 100 (please refer to FIG. 2), and a band offset between a valence band of the strained quantum well layer 110 and a valence band of the second barrier layer 120 is less than a band offset between a conduction band of the second barrier layer 120 and a conduction band of the strained quantum well layer 110 (please refer to FIG. 2).

In FIG. 2, the energy band of the first strained barrier layer 100, the energy band of the strained quantum well layer 110, and the energy band of the second barrier layer 120 are represented from left to right.

In FIG. 2, E_{g1} is the band gap of the first strained barrier layer 100 in the present embodiment, E_{g2} is the band gap of the second barrier layer 120 in the present embodiment, E_{g3} is the band gap of the strained quantum well layer 110 in the present embodiment, E_{g2}=E_{g1}; ΔEᵥ₁ is the band offset between the valence band of the strained quantum well layer 110 and the valence band of the first strained barrier layer 100 in the present embodiment, ΔEᵥ₂ is the band offset between the valence band of the strained quantum well layer 110 and the valence band of the second barrier layer 120 in the present embodiment, ΔE_{c1} is the band offset between the conduction band of the first strained barrier layer 100 and the conduction band of the strained quantum well layer 110 in the present embodiment, and ΔE_{c2} is the band offset between the conduction band of the second barrier layer 120 and the conduction band of the strained quantum well layer 110 in the present embodiment. The second barrier layer 120 in FIG. 2 is a strain-free barrier layer.

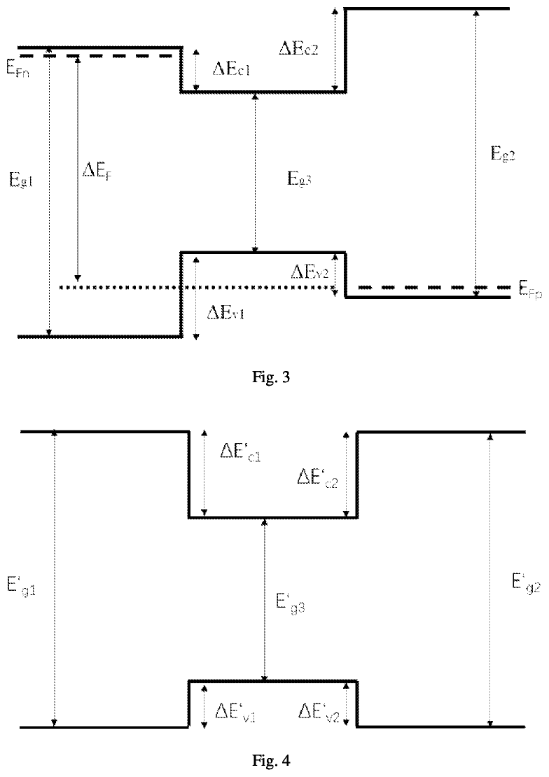

FIG. 3 is a schematic diagram of the barrier quasi-fermi level in the high-efficiency active layer in the present embodiment. The turn-on voltage ΔV_{F} is in direct proportion to the sum of the band gap of the strained quantum well layer 110, the band offset between the conduction bands of the first strained barrier layer 100 and the strained quantum well layer 110, and the band offset between the valence bands of the strained quantum well layer 110 and the second barrier layer 120.

Due to a smaller band offset between the conduction band of the first strained barrier layer 100 and the conduction band of the strained quantum well layer 110, the barrier of the first strained barrier layer 100 to electrons is reduced, therefore, the ability of conducting electrons in the first strained barrier layer 100 is better, and more electrons can be transferred to the strained quantum well layer 110. Due to a larger band offset between the valence band of the strained quantum well layer 110 and the valence band of the first strained barrier layer 100, the first strained barrier layer 100 can block the conduction of holes from the strained quantum well layer 110 to the first strained barrier layer 100, and suppress hole leakage, and more holes can be located in the strained quantum well layer 110, thereby enhancing the recombination efficiency of holes and electrons and improving the light-emitting efficiency. Due to the smaller band offset between the valence band of the strained quantum well layer 110 and the valence band of the second barrier layer 120, the barrier of the second barrier layer 120 to holes is reduced, therefore, the ability of conducting holes in the second barrier layer 120 is better, and more holes can be transferred to the strained quantum well layer 110. The band offset between the conduction band of the second barrier layer 120 and the conduction band of the strained quantum well layer 110 is large, so the second barrier layer 120 can block the conduction of electrons from the strained quantum well layer 110 to the second barrier layer 120, and suppress electron leakage, and more electrons can be located in the strained quantum well layer 110, thereby enhancing the recombination efficiency of holes and electrons, and improving the light-emitting efficiency.

Secondly, the strained quantum well layer 110 is strained, such that the light hole valence band is separated from the heavy hole valence band of the strained quantum well layer 110, the light hole valence band of the strained quantum well layer 110 or the heavy hole valence band of the strained quantum well layer 110 serve as a top layer of the valence band for energy level conversion. Through such a structural design, a gain effect of the strained quantum well layer 110 is enhanced, and the state density of the valence band of the strained quantum well layer 110 participating in light lasing is smaller, therefore, when the energy level difference between the two is larger, a higher gain effect is obtained, and the light-emitting efficiency is improved. In addition, the first strained barrier layer 100 and the strained quantum well layer 110 form strain compensation, thereby being conducive to increasing long-term stability of the strained quantum well layer 110 and improving reliability.

Thirdly, a smaller band offset between the conduction bands of the first strained barrier layer and the strained quantum well layer and a smaller band offset between the valence bands of the strained quantum well layer and the second barrier layer can be obtained simultaneously, and the turn-on voltage of a PN junction can be reduced.

The first strained barrier layer 100 and the strained quantum well layer 110 are configured to form strain compensation. In one embodiment, the strained quantum well layer 110 is a tensile strained quantum well layer, and the first strained barrier layer 100 is a compressive strained quantum well layer. In another embodiment, the strained quantum well layer 110 is a compressive strained quantum well layer, and the first strained barrier layer 100 is a tensile strained quantum well layer.

In the present embodiment, the first strained barrier layer 100 is in contact with the strained quantum well layer 110, and the second barrier layer 120 is in contact with the strained quantum well layer 110.

In the present embodiment, the second barrier layer 120 is a strain-free barrier layer.

In the present embodiment, the band offset between the conduction band of the first strained barrier layer 100 and the conduction band of the strained quantum well layer 110 is less than the band offset between the conduction band of the second barrier layer 120 and the conduction band of the strained quantum well layer 110; and the band offset between the valence band of the strained quantum well layer 110 and the valence band of the second barrier layer 120 is less than the band offset between the valence band of the strained quantum well layer 110 and the valence band of the first strained barrier layer 100.

In one embodiment, the band gap of the first strained barrier layer is equal to the band gap of the second barrier layer. In other embodiments, the band gap of the first strained barrier layer is not equal to the band gap of the second barrier layer.

### Embodiment 2

On the basis of Embodiment 1, the present embodiment further defines that the luminous waveband of the high-efficiency active layer is in a range of 750 nm to 860 nm; the strained quantum well layer 110 is a tensile strained quantum well layer, and the first strained barrier layer 100 is a compressive strained barrier layer; the material of the tensile strained quantum well layer includes GaAsₓ₃P₁₋ₓ₃; the material of the compressive strained barrier layer includes Inₓ₁Ga₁₋ₓ₁P; and the material of the second barrier layer includes Alₓ₂Ga₁₋ₓ₂As.

In the present embodiment, the strained quantum well layer 110 is a tensile strained quantum well layer, such that the light hole valence band is separated from the heavy hole valence band of the valence band of the tensile strained quantum well layer. The light hole valence band of the tensile strained quantum well layer is close to the conduction band of the tensile strained quantum well layer relative to the heavy hole valence band of the tensile strained quantum well layer, and the light hole valence band of the tensile strained quantum well layer serves as a top layer of the valence band for energy level conversion. Through such a structural design, a gain effect of the tensile strained quantum well layer is enhanced, and the state density of the valence band of the tensile strained quantum well layer participating in light lasing is smaller (relative to the state density of the valence band of a quantum well layer when the light hole valence band of the quantum well layer is overlapped with the heavy hole valence band), when the energy level difference between the two is larger, a higher gain effect is obtained, and the light-emitting efficiency is improved.

In addition, the first strained barrier layer 100 is a compressive strained barrier layer. The compressive strained barrier layer and the tensile strained quantum well layer form strain compensation, thereby being conducive to enhancing long-term stability of the tensile strained quantum well layer, enhancing the gain effect of the tensile strained quantum well layer, and improving the reliability.

In addition, no Al element is available in the tensile strained quantum well layer, thereby improving the reliability of the tensile strained quantum well layer.

Thirdly, a smaller band offset between the conduction bands of the compressive strained barrier layer and the tensile strained quantum well layer and a smaller band offset between the valence bands of the tensile strained quantum well layer and the second barrier layer can be obtained simultaneously, and the turn-on voltage of a PN junction can be reduced.

In the present embodiment, the second barrier layer 120 is a strain-free barrier layer.

In one embodiment, x1 ranges from 0.51 to 0.65; x2 ranges from 0.2 to 0.4, and x3 ranges from 0.70 to 0.95.

When the material of the tensile strained quantum well layer is GaAsₓ₃P₁₋ₓ₃, the composition of P in the tensile strained quantum well layer is increased, and a tensile stress of the tensile strained quantum well layer becomes larger, when the tensile stress of the tensile strained quantum well layer is larger, it is more helpful for increasing the difference between the light hole valence band energy level and the heavy hole valence band energy level. The composition of P in the tensile strained quantum well layer is increased, such that the band gap of the tensile strained quantum well layer becomes larger, and the wavelength of the light emitted by the tensile strained quantum well layer moves towards the short wave direction. Secondly, the growth quality of the tensile strained quantum well layer needs to be considered. If the composition of P is too large, there will be challenges for the epitaxial growth of the tensile strained quantum well layer. Therefore, in one optional embodiment, x3 ranges from 0.70 to 0.95.

In one embodiment, the thickness of the tensile strained quantum well layer is in a range of 8 nm to 20 nm, such as 8 nm, 10 nm, 12 nm, 15 nm, 18 nm or 20 nm. The advantage of such a setting is as follows: when the thickness of the tensile strained quantum well layer is greater than 8 nm, as the thickness of the tensile strained quantum well layer increases, the difference between the conduction band energy level and the heavy hole valence band energy level of the tensile strained quantum well layer becomes smaller, and the difference between the conduction band energy level and the light hole valence band energy level of the tensile strained quantum well layer becomes smaller. The light hole band of the tensile strained quantum well layer is used as a top layer of the valence band for energy level conversion, the degree to which the difference between the conduction band energy level and the light hole valence band energy level of the tensile strained quantum well layer becomes smaller with an increase in thickness is large, therefore, a higher gain effect is obtained.

In one optional embodiment, the thickness of the tensile strained quantum well layer is in a range of 8 nm to 20 nm, x3 is 0.82, and a difference between the light hole valence band energy level and the heavy hole valence band energy level which is greater than 30 meV is obtained to obtain a better gain.

FIG. 6 is a diagram showing the relationship between the thickness of the tensile strained quantum well layer and the difference between the conduction band energy level and the light hole valence band energy level of the tensile stress quantum well layer and the relationship between the thickness of the tensile strained quantum well layer and the difference between the conduction band energy level and the heavy hole valence band energy level of the tensile strained quantum well layer aiming at tensile strained quantum well layers of different thickness, and the material of the tensile strained quantum well layer is GaAs_{0.82}P_{0.18}. It can be known from FIG. 6 that as the thickness of the tensile strained quantum well layer increases, the difference between the conduction band energy level and the heavy hole valence band energy level of the tensile strained quantum well layer becomes smaller, the difference between the conduction band energy level and the light hole valence band energy level of the tensile strained quantum well layer becomes smaller, and the degree to which the difference between the conduction band energy level and the light hole valence band energy level of the tensile strained quantum well layer becomes smaller with an increase in thickness is greater than the degree to which the difference between the conduction band energy level and the heavy hole valence band energy level of the tensile strained quantum well layer becomes smaller with an increase in thickness. For the tensile strained quantum well layer, the light hole band of the tensile strained quantum well layer serves as a top layer of the valence band for energy level conversion, since the degree to which the difference between the conduction band energy level and the light hole valence band energy level of the tensile strained quantum well layer becomes smaller with an increase in thickness is large, a higher gain effect can be obtained.

When the material of the tensile strained quantum well layer is GaAsₓ₃P₁₋ₓ₃, and the thickness of the tensile strained quantum well layer is in a range of 8 nm to 20 nm, the tensile strain variable of the tensile strained quantum well layer is 0.5% to 1.5%, such as 0.5%, 0.8%, 1.0%, 1.2% or 1.5%.

In one embodiment, the thickness of the first strained barrier layer 100 is in a range of 5 nm to 30 nm.

When the material of the compressive strained barrier layer is Inₓ₁Ga₁₋ₓ₁P, and the thickness of the compressive strained barrier layer is in a range of 5 nm to 30 nm, the compressive strain variable of the compressive strained barrier layer is 0.1% to 0.8%, such as 0.1%, 0.2%, 0.3%, 0.4%, 0.5%, 0.6%, 0.7% or 0.8%.

In one embodiment, the thickness of the second barrier layer 120 is in a range of 5 nm to 30 nm.

The second barrier layer 120 is a strain-free barrier layer.

In one embodiment, the band offset between the conduction band of the compressive strained barrier layer and the conduction band of the tensile strained quantum well layer is a first band offset; the band offset between the valence band of the tensile strained quantum well layer and the valence band of the compressive strained barrier layer is a second band offset; the ratio of the first band offset to the second band offset is in a range of 35/65 to 47/53.

If the band offset between the valence band of the tensile strained quantum well layer and the valence band of the compressive strained barrier layer is too small, the degree to which the compressive strained barrier layer can block conduction of holes from the tensile strained quantum well layer to the compressive strain barrier layer is weakened; if the band offset between the valence band of the tensile strained quantum well layer and the valence band of the compressive strained barrier layer is too large, then the band gap of the compressive strained barrier layer is too large, and the turn-on voltage is increased. In the present embodiment, the ratio of the first band offset to the second band offset is in a range of 35/65 to 47/53, taking into account the blocking of hole leakage and the lower turn-on voltage. In one embodiment, the ratio of the first band offset to the second band offset is 2:3.

In one embodiment, the band offset between the valence band of the tensile strained quantum well layer and the valence band of the second barrier layer 120 is a third band offset; the band offset between the conduction band of the second barrier layer 120 and the conduction band of the tensile strained quantum well layer is a fourth band offset; and the ratio of the third band offset to the fourth band offset is in a range of 35/65 to 47/53.

If the band offset between the conduction band of the second barrier layer 120 and the conduction band of the tensile strained quantum well layer is too small, the degree to which the second barrier layer 120 can block conduction of electrons from the tensile strained quantum well layer to the second barrier layer 120 is weakened; if the band offset between the conduction band of the second barrier layer 120 and the conduction band of the tensile strained quantum well layer is too large, then the band gap of the second barrier layer 120 is too large, and the turn-on voltage is increased. In the present embodiment, the ratio of the third band offset to the fourth band offset is in a range of 35/65 to 47/53, taking into account the blocking of electron leakage and the lower turn-on voltage. In one embodiment, the ratio of the third band offset to the fourth band offset is 2:3.

It should be noted that the present embodiment focuses on the asymmetric first strained barrier layer 100 and second barrier layer 120. The benefits of the asymmetric first strained barrier layer 100 and second barrier layer 120 of the present embodiment will be described below in combination with Comparative Example 1 and Comparative Example 2.

FIG. 4 is an energy band diagram of an active layer provided in Comparative Example 1, and the active layer of Comparative Example 1 includes a first barrier layer, a second barrier layer and a quantum well layer, wherein the first barrier layer and the second barrier layer are located on both sides of the quantum well layer, and the materials of the first barrier layer and the second barrier layer are the same, the material of the quantum well layer in Comparative Example 1 is consistent with the material of the tensile strained quantum well layer in the present embodiment. The second barrier layer in the Comparative Example 1 is consistent with the second barrier layer of the present embodiment, and the materials of the first barrier layer and the second barrier layer are all strain-free Alₓ₂Ga₁₋ₓ₂As, and the quantum well layer in Comparative Example 1 is tensile strained GaAsₓ₃P₁₋ₓ₃.

In FIG. 4, E′_{g1} is the band gap of the first barrier layer in Comparative Example 1, E′_{g2} is the band gap of the second barrier layer in Comparative Example 1, E′_{g3} is the band gap of the quantum well layer in Comparative Example 1, and E′_{g2}=E′_{g1}=E_{g1}; ΔE′ᵥ₁ is the band offset between the valence band of the quantum well layer and the valence band of the first barrier layer in Comparative Example 1, ΔE′ᵥ₂ is the band offset between the valence band of the quantum well layer and the valence band of the second barrier layer in Comparative Example 1, ΔE′_{c1} is the band offset between the conduction band of the first barrier layer and the conduction band of the quantum well layer in Comparative Example 1, and ΔE′_{c2} is the band offset between the conduction band of the second barrier layer and the conduction band of the quantum well layer in Comparative Example 1.

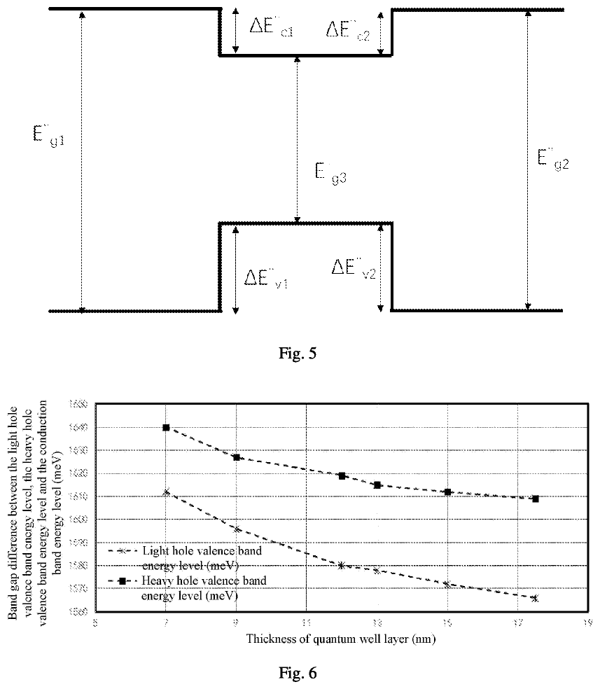

FIG. 5 is an energy band diagram of an active layer provided in Comparative Example 2. The active layer of Comparative Example 2 includes a first barrier layer, a second barrier layer and a quantum well layer, wherein the first barrier layer and the second barrier layer are located on both sides of the quantum well layer, the materials of the first barrier layer and the second barrier layer are the same. The quantum well layer is tensile strained GaAsₓ₃P₁₋ₓ₃, and the materials of the first barrier layer and the second barrier layer are compressive strained Inₓ₁Ga₁₋ₓ₁P.

In FIG. 5, E″_{g1} is the band gap of the first barrier layer in Comparative Example 2, E″_{g2} is the band gap of the second barrier layer in Comparative Example 2, E″_{g3} is the band gap of the quantum well layer in Comparative Example 2, E″_{g2}=E″_{g1}=E_{g1}; ΔE″ᵥ₁ is the band offset between the valence band of the quantum well layer and the valence band of the first barrier layer in Comparative Example 2, ΔE″ᵥ₂ is the band offset between the valence band of the quantum well layer and the valence band of the second barrier layer in Comparative Example 2, ΔE″_{c1} is the band offset between the conduction band of the first barrier layer and the conduction band of the quantum well layer in Comparative Example 2, and ΔE″_{c2} is the band offset between the conduction band of the second barrier layer and the conduction band of the quantum well layer in Comparative Example 2.

In the present embodiment, the energy loss during injection of electrons and holes into the tensile strained quantum well layer is in direct proportion to the sum of the band offset between the conduction bands between the first strained barrier layer and the tensile strained quantum well layer and the band offset of valence bands between the tensile strained quantum well layer and the second barrier layer.

In the present embodiment, ΔEₛ=a1*ΔE_{c1}+a2*ΔEᵥ₂, a1 and a2 are constant coefficients greater than 0, and ΔEₛ is the energy loss during injection of electrons and holes into the tensile strained quantum well layer in the present embodiment. In Comparative Example 1, ΔE′ₛ=a1*ΔE′_{c1}+a2*ΔE′ᵥ₂, a1 and a2 are constant coefficients greater than 0, and ΔE′ₛ is the energy loss during injection of electrons and holes into the quantum well layer in Comparative Example 1. In Comparative Example 2, ΔE″ₛ=a1*ΔE″_{c1}+a2*ΔE″ᵥ₂, a1 and a2 are constant coefficients greater than 0, and ΔE″ₛ is the energy loss during injection of electrons and holes into the quantum well layer in Comparative Example 2.

In the present embodiment, ΔE_{c1} is 0.4*ΔE_{g1}, and ΔEᵥ₂ is 0.4*ΔE_{g2}. ΔE_{g1}=E_{g1}-E_{g3}, ΔE_{g2}=E_{g2}-E_{g3}. Correspondingly, ΔEₛ=a1*0.4*ΔE_{g1}+a2*0.4*ΔE_{g2}.

In Comparative Example 1, ΔE′_{c1} is 0.6*ΔE′_{g1}, ΔE′ᵥ₂ is 0.4*ΔE′_{g2}. ΔE′_{g1}=E′_{g1}-E′_{g3}, and ΔE′_{g2}=E′_{g2}-E′_{g3}. Correspondingly, ΔE′ₛ=a1*0.6*ΔE′_{g1}+a2*0.4*ΔE′_{g2}. ΔE′_{g1}=ΔE′_{g2}.

In Comparative Example 2, ΔE″_{c1} is 0.4*ΔE″_{g1}, ΔE″ᵥ₂ is 0.6*ΔE″_{g2}. ΔE″_{g1}=E″_{g1}-E″_{g3}, ΔE″_{g2}=E″_{g2}-E″_{g3}. Correspondingly, ΔE″ₛ=a1*0.4*ΔE″_{g1}+a2*0.6*ΔE″_{g2}. ΔE″_{g1}=ΔE″_{g2}.

Since the material of the second barrier layer adopted in Comparative Example 1 is consistent with that of the present embodiment, the material of the quantum well layer adopted in Comparative Example 1 is consistent with the material of the tensile strained quantum well layer adopted in the present embodiment, so ΔE′_{g2}=ΔE_{g2}. ΔEₛ-ΔE′ₛ=a1*0.4*ΔE_{g1}+a2*0.4*ΔE_{g2}-a1*0.6*ΔE′_{g1}-a2*0.4*ΔE′_{g2}=a1*0.4*ΔE_{g1}-a1*0.6*ΔE′_{g1}=−a1*0.2*ΔE_{g1}<0. Therefore, ΔEₛ<ΔE′ₛ.

Since the first barrier layer adopted in Comparative Example 2 is consistent with the material of the first strained barrier layer adopted in the present embodiment, the material of the quantum well layer adopted in Embodiment 2 is correspondingly consistent with the material of the tensile strained quantum well layer adopted in the present embodiment, so ΔE″_{g1}=ΔE_{g1}. ΔEₛ-ΔE″ₛ=a1*0.4*ΔE_{g1}+a2*0.4*ΔE_{g2}-a1*0.4*ΔE″_{g1}-a2*0.6*ΔE″_{g2}=a2*0.4*ΔE_{g2}-a2*0.6*ΔE″_{g2}=−a2*0.2*ΔE_{g2}<0. Therefore, ΔEₛ<ΔE″ₛ.

According to the above analysis: in the present embodiment, the material of the tensile strained quantum well layer is GaAsₓ₃P₁₋ₓ₃, the material of the first strained barrier layer 100 is Inₓ₁Ga₁₋ₓ₁P, and the band offset ΔE_{c1} of the conduction bands between the first strained barrier layer 100 and the tensile strained quantum well layer is small, which can reduce the energy loss during injection of electron carriers; at the same time, the material of the second barrier layer 120 is Alₓ₂Ga₁₋ₓ₂As, and the band offset ΔEᵥ₂ of the valence bands between the tensile strained quantum well layer and the second barrier layer 120 is small, which can reduce the energy loss during injection of hole carriers. The arrangement of the asymmetric first strained barrier layer 100 and the second barrier layer 120 enables the active layer to have the lowest energy loss during injection of carriers, that is, the largest energy quantum efficiency.

In the present embodiment, the proportion of carriers injected into the tensile strained quantum well layer and escaped is associated with its escape barrier. In the present embodiment, the ratio Se of electrons escaping from the tensile strained quantum well layer is positively correlated with the band offset between the conduction bands of the tensile strained quantum well layer and the second barrier layer 120, that is, Se=b₁*exp(−ΔE_{c2}/k₀T), where k₀ is Boltzmann constant 1.380649×10⁻²³J/K; T is the temperature (K) of the tensile strained quantum well layer. In the present embodiment, the ratio Sn of holes escaping from the tensile strained quantum well layer is positively correlated with the band offset between the valence bands of the tensile strained quantum well layer and the first strained barrier layer, that is, Sn=b₂*exp(−ΔEᵥ₁/k₀T). b₁ is a coefficient of Se, and b₂ is a coefficient of Sn.

In Comparative Example 1, the ratio Se′ of electrons escaping from the quantum well layer is positively correlated with the band offset between the conduction bands of the quantum well layer and the second barrier layer, that is, Se′=b₁*exp(−ΔE′_{c2}/k₀T), the ratio Sn′ of the holes escaping from the quantum well layer is positively correlated with the band offset between the valence bands of the quantum well layer and the first barrier layer, Sn′=b₂*exp(−ΔE′ᵥ₁/k₀T). b₁ is the coefficient of Se′, b₂ is the coefficient of Sn′, and T is the temperature of the quantum well layer.

In Comparative Example 2, the ratio Se″ of electrons escaping from the quantum well layer is positively correlated with the band offset between the conduction bands of the quantum well layer and the second barrier layer, that is, Se″=b₁*exp(−ΔE″_{c2}/k₀T), the ratio Sn″ of holes escaping from the quantum well layer is positively correlated with the band offset between the valence bands of the quantum well layer and the first barrier layer, Sn″=b₂*exp(−ΔE″ᵥ₁/k₀T). b₁ is the coefficient of Se″, b₂ is the coefficient of Sn″, and T is the temperature of the quantum well layer.

In the present embodiment, the relationship between the high-efficiency active layer with a luminous wavelength of 750 nm to 860 nm and the escape ratio is as follows:

$$η = ( 1 - {b}_{1} exp ( - \frac{Δ {E}_{{C}_{2}}}{{k}_{0} T} ) ) * ( 1 - {b}_{2} exp ( - \frac{Δ {E}_{{V}_{1}}}{{k}_{0} T} ) ) .$$

In Comparative Example 1, the relationship between the quantum efficiency η′ of the active layer and the escape ratio is as follows:

$${η}^{′} = ( 1 - {b}_{1} exp ( - \frac{Δ E {′}_{{C}_{2}}}{{k}_{0} T} ) ) * ( 1 - {b}_{2} exp ( - \frac{Δ E {′}_{{V}_{1}}}{{k}_{0} T} ) )$$

In Comparative Example 1, the relationship between the quantum efficiency η′ of the active layer and the escape ratio is as follows:

$${η}^{′′} = ( 1 - {b}_{1} exp ( - \frac{Δ E {′′}_{{C}_{2}}}{{k}_{0} T} ) ) * ( 1 - {b}_{2} exp ( - \frac{Δ E {′′}_{{V}_{1}}}{{k}_{0} T} ) )$$

$$\frac{η}{{η}^{′}} = ( 1 - {b}_{2} exp ( - \frac{Δ {E}_{V 1}}{{k}_{0} T} ) ) / ( 1 - {b}_{2} exp ( - \frac{Δ E {′}_{V 1}}{{k}_{0} T} ) ) = ( 1 - {b}_{2} exp ( - \frac{0.6 * Δ Eg 1}{{k}_{0} T} ) ) / ( 1 - {b}_{2} exp ( - \frac{0.4 * Δ E ′ g 1}{{k}_{0} T} ) ) > 1$$

$$\frac{η}{{η}^{″}} ( 1 - {b}_{1} exp ( - \frac{Δ {E}_{{C}_{2}}}{{k}_{0} T} ) ) / ( 1 - {b}_{1} exp ( - \frac{Δ E {″}_{{C}_{2}}}{{k}_{0} T} ) ) = ( 1 - {b}_{1} exp ( - \frac{0.6 * Δ Eg 2}{{k}_{0} T} ) ) / ( 1 - {b}_{1} exp ( - \frac{0.4 * Δ E ′′ g 2}{{k}_{0} T} ) ) > 1$$

$$Therefore ,$$

$$η > η′ ,$$

$$η > η′′ .$$

According to the above analysis, in the present embodiment, the material of the tensile strained quantum well layer is GaAsₓ₃P₁₋ₓ₃, the material of the first strained barrier layer 100 is Inₓ₁Ga₁₋ₓ₁P, and the band offset ΔEᵥ₁ between the valence bands of the tensile strained quantum well layer and the first strained barrier layer 100 is larger; the ability of blocking hole carriers by the first strained barrier layer 100 is enhanced, to better block holes transferred from the tensile strained quantum well layer to the first strained barrier layer 100 on the valence band, such that the holes are better confined in a potential well of the tensile strained quantum well layer. At the same time, the material of the second barrier layer 120 is Alₓ₂Ga₁₋ₓ₂As. The band offset ΔE_{c2} between the conduction bands of the tensile strained quantum well layer and the second barrier layer 120 is larger, the ability of blocking electrons by the second barrier layer 120 is enhanced, to better block electrons transferred from the tensile strained quantum well layer to the second strained barrier layer 120 on the conduction band, such that the electrons are better confined in a potential well of the tensile strained quantum well layer.

In the present embodiment, unsymmetrical first strained barrier layer and second barrier layer are adopted, which is beneficial for reducing the turn-on voltage of the active layer and further improving the light-emitting efficiency.

In the present embodiment, the turn-on voltage is in direct proportion to the sum of the band gap of the tensile strained quantum well layer, the band offset between the conduction bands of the first strained barrier layer and the tensile strained quantum well layer and the band offset between the valence bands of the tensile strained quantum well layer and the second barrier layer.

In the present embodiment, the third voltage V₃ which is associated with the band gap of the tensile strained quantum well layer is equal to E_{g3}/e, wherein e is an electron charge; the voltage positively correlated with the band offset ΔE_{c1} between the conduction bands of the first strained barrier layer and the tensile strained quantum well layer is the first voltage drop V₁, V₁=q1*ΔE_{c1}, q1>0; the voltage positively correlated with the band offset ΔEᵥ₂ between the valence bands of the tensile strained quantum well layer and the second barrier layer is the second voltage drop V₂, V₂=q2*ΔEᵥ₂, q2>0; the turn-on voltage is as follows: ΔV_{F}=V₁+V₂+V₃=q1*ΔE_{c1}+q2*ΔEᵥ₂+E_{g3}/e=q1*0.4*ΔE_{g1}+q2*0.4*ΔE_{g2}+E_{g3}/e. ΔV_{F} corresponds to ΔE_{F}.

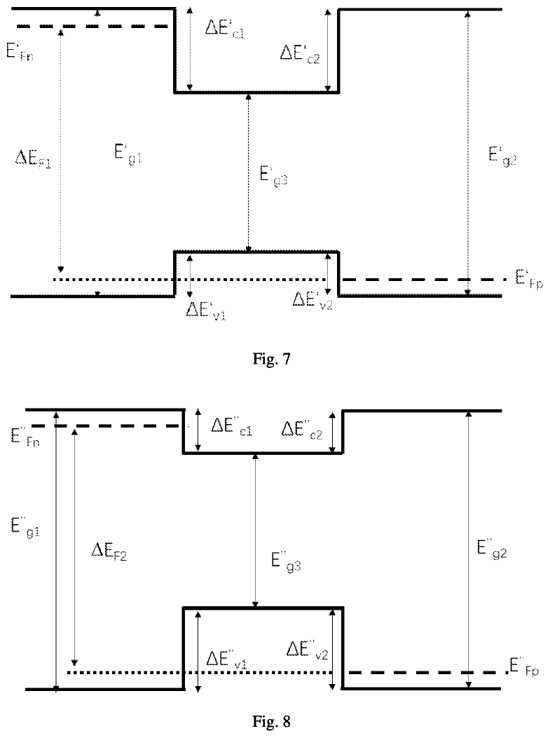

Please refer to FIG. 7, in Comparative Example 1, a third voltage V′₃ which is associated with the band gap of the quantum well layer is equal to E′_{g3}/e, wherein e is an electron charge; the voltage positively correlated with the band offset ΔE′_{c1} between the conduction bands of the first barrier layer and the quantum well layer is V′₁; V′₁=q1*ΔE′_{c1}, q1>0; the voltage positively correlated with the band offset ΔE′ᵥ₂ between the valence bands of the quantum well layer and the second barrier layer is the second voltage drop V′₂, V′₂=q2*ΔE′ᵥ₂, q2>0; the turn-one voltage is as follows: ΔV_{F1}=V′₁+V′₂+V′₃=q1*ΔE′_{c1}+q2*ΔE′ᵥ₂+E′_{g3}/e=q1*0.6*ΔE′_{g1}+q2*0.4*ΔE′_{g2}+E′_{g3}/e. ΔV_{F1} corresponds to ΔE_{F1}.

Please refer to FIG. 8, in Comparative Example 2, the third voltage V″₃ which is associated with the band gap of the quantum well layer is equal to E″_{g3}/e, wherein e is an electron charge; the voltage positively correlated with the band offset ΔE″_{c1} between the conduction bands of the first barrier layer and the quantum well layer is the first voltage drop V″₁, V″₁=q1*ΔE″_{c1}, q1>0; the voltage positively correlated with the band offset ΔE″ᵥ₂ between the valence bands of the quantum well layer and the second barrier layer is the second voltage drop V″₂, V″₂=q2*ΔE″ᵥ₂, q2>0; the turn-on voltage is as follows: ΔV_{F2}=V″₁+V″₂+V″₃=q1*ΔE″_{c1}+q2*ΔE″ᵥ₂+E″_{g3}/e=q1*0.4*ΔE″_{g1}+q2*0.6*ΔE″_{g2}+E″_{g3}/e. ΔV_{F2} corresponds to ΔE_{F2}.

$$Δ {V}_{F} - Δ {V}_{F 1} = q 1 * 0.4 * Δ {E}_{g 1} + q 2 * 0.4 * Δ {E}_{g 2} + {E}_{g 3} / e - ( q 1 * 0.6 * Δ {{E}^{′}}_{g 1} + q 2 * 0.4 * Δ {{E}^{′}}_{g 2} + Δ {{E}^{′}}_{g 3} / e ) = q 1 * 0.4 * Δ {E}_{g 1} - q 1 * 0.6 * Δ {{E}^{′}}_{g 1} = - q 1 * 0.2 * Δ {E}_{g 1} / e < 0.$$

$$Δ {V}_{F} < Δ {V}_{F 1} .$$

$$Δ {V}_{F} - Δ {V}_{F 2} = q 1 * 0.4 * Δ {E}_{g 1} + q 2 * 0.4 * Δ {E}_{g 2} + {E}_{g 3} / e - ( q 1 * 0.4 * Δ {{E}^{′′}}_{g 1} + q 2 * 0.6 * Δ {{E}^{′′}}_{g 2} + {{E}^{′′}}_{g 3} / e ) = q 2 * 0.4 * Δ {E}_{g 2} - q 2 * 0.6 * Δ {{E}^{′′}}_{g 2} = - q 2 * 0.2 * Δ E = / e < 0.$$

$$Δ {V}_{F} < Δ {V}_{F 2} .$$

In the present embodiment, a smaller band offset between the conduction bands of the compressive strained barrier layer and the tensile strained quantum well layer and a smaller band offset between the valence bands of the tensile strained quantum well layer and the second barrier layer can be obtained simultaneously, and the turn-on voltage of a PN junction can be reduced.

In the prior art, the quantum well layer adopted by the active layer in a luminous waveband of 750 nm to 860 nm is an ALGaInAs quantum well layer, the ALGaInAs quantum well layer has an Al-containing structure, the content of Al is high, and Al is easy to oxidize and easy to produce defects in the material, nonradiative recombination is increased, therefore, on the one hand, the performance is reduced, and on the other hand, the reliability is reduced.

In the present embodiment, the material of the tensile strained quantum well layer does not contain Al, thereby avoiding oxidation of the material in the tensile strained quantum well layer and avoiding generating defects, avoiding an increase of nonradiative recombination, and improving the reliability of the quantum well layer.

The same contents of Embodiment 2 as those of Embodiment 1 will not be described in details.

### Embodiment 3

On the basis of Embodiment 1, the present embodiment further defines that the luminous waveband of the high-efficiency active layer is in a range of 870 nm to 1100 nm; the strained quantum well layer 110 is a compressive strained quantum well layer, and the first strained barrier layer 100 is a tensile strained barrier layer; the material of the compressive strained quantum well layer includes Inₓ₆Ga₁₋ₓ₆As; the material of the tensile strained barrier layer includes GaAsₓ₄P₁₋ₓ₄; and the material of the second barrier layer includes Alₓ₅Ga₁₋ₓ₅As.

In the present embodiment, the strained quantum well layer 110 is a compressive strained quantum well layer, such that the light hole valence band is separated from the heavy hole valence band of the valence band of the compressive strained quantum well layer. The heavy hole valence band of the compressive strained quantum well layer is close to the conduction band of the compressive strained quantum well layer relative to the light hole valence band of the compressive strained quantum well layer, and the heavy hole valence band of the compressive strained quantum well layer serves as a top layer of the valence band for energy level conversion. Through such a structural design, a gain effect of the compressive strained quantum well layer is enhanced, and the state density of the valence band of the compressive strained quantum well layer participating in light lasing is smaller (relative to the state density of the valence band of a quantum well layer when the light hole valence band of the quantum well layer is overlapped with the heavy hole valence band), when the energy level difference between the two is larger, a higher gain effect is obtained, and the light-emitting efficiency is improved.

In addition, the first strained barrier layer 100 is a tensile strained barrier layer. The tensile strained barrier layer and the compressive strained quantum well layer form strain compensation, thereby being conducive to enhancing the gain effect of the compressive strained quantum well layer, enhancing long-term stability of the compressive strained quantum well layer, and improving the reliability.

Secondly, no Al element is available in the compressive strained quantum well layer, thereby improving the reliability of the compressive strained quantum well layer.

Thirdly, a smaller band offset between the conduction bands of the tensile strained barrier layer and the compressive strained quantum well layer and a smaller band offset between the valence bands of the compressive strained quantum well layer and the second barrier layer can be obtained simultaneously, and the turn-on voltage of a PN junction can be reduced.

In the present embodiment, the second barrier layer 120 is a strain-free barrier layer.

In one embodiment, x4 ranges from 0.7 to 0.95; x5 ranges from 0.05 to 0.3, and x6 ranges from 0.1 to 0.3.

When the material of the compressive strained quantum well layer is Inₓ₆Ga₁₋ₓ₆As, the composition of In in the compressive strained quantum well layer is increased, and the compressive stress of the compressive strained quantum well layer becomes larger, when the compressive stress of the compressive strained quantum well layer is larger, it is more helpful for increasing the difference between the light hole valence band energy level and the heavy hole valence band energy level. The composition of In in the compressive strained quantum well layer is increased, such that the band gap of the compressive strained quantum well layer becomes larger, and the wavelength of the light emitted by the compressive strained quantum well layer moves towards the long wave direction. Secondly, the growth quality of the compressive strained quantum well layer needs to be considered. If the composition of In in the compressive strained quantum well layer is too large, there will be challenges for epitaxial growth of the compressive strained quantum well layer. Therefore, in one optional embodiment, x6 is 0.1 to 0.3.

In one embodiment, the thickness of the compressive strained quantum well layer is in a range of 4 nm to 8 nm, such as 4 nm, 5 nm, 6 nm, 7 nm, or 8 nm.

When the material of the compressive strained quantum well layer is Inₓ₆Ga₁₋ₓ₆As and the thickness of the compressive strained quantum well layer is in a range of 4 nm to 8 nm, the compressive stress variable of the compressive strained quantum well layer ranges from 0.1% to 2%, for example, 0.1%, 0.2%, 0.5%, 0.8%, 1.0%, 1.2%, 1.5% or 2%.

In one embodiment, the thickness of the first strained barrier layer is in a range of 4 nm to 50 nm.

When the material of the tensile strained barrier layer is GaAsₓ₄P₁₋ₓ₄ and the thickness of the tensile strained barrier layer is in a range of 4 nm to 50 nm, the tensile strained variable of the tensile strained barrier layer ranges from 0.1% to 2%, for example, 0.1%, 0.2%, 0.5%, 0.8%, 1.0%, 1.2%, 1.5% or 2%.

In one embodiment, the thickness of the second strained barrier layer 120 is in a range of 5 nm to 30 nm.

In the present embodiment, the band offset between the conduction band of the tensile strained barrier layer and the conduction band of the compressive strained quantum well layer is less than the band offset between the conduction band of the second barrier layer 120 and the conduction band of the compressive strained quantum well layer; and the band offset between the valence band of the compressive strained quantum well layer and the valence band of the second barrier layer 120 is less than the band offset between the valence band of the compressive strained quantum well layer and the valence band of the tensile strained barrier layer.

In one embodiment, the band offset between the conduction band of the tensile strained barrier layer and the conduction band of the compressive strained quantum well layer is a first band offset; the band offset between the valence band of the compressive strained quantum well layer and the valence band of the tensile strained barrier layer is a second band offset; the ratio of the first band offset to the second band offset is in a range of 30/70 to 45/55.

If the band offset between the valence band of the compressive strained quantum well layer and the valence band of the tensile strained quantum well layer is too small, the degree to which the tensile strained barrier layer can block conduction of holes from the compressive strained quantum well layer to the tensile strained barrier layer is weakened; if the band offset between the valence band of the compressive strained quantum well layer and the valence band of the tensile strained barrier layer is too large, then the band gap of the tensile strained barrier layer is too large, and the turn-on voltage is increased. In the present embodiment, the ratio of the first band offset to the second band offset is in a range of 30/70 to 45/55, taking into account the blocking of hole leakage and the lower turn-on voltage. In one embodiment, the ratio of the first band offset to the second band offset is 2:3.

In one embodiment, the band offset between the valence band of the compressive strained quantum well layer and the valence band of the second barrier layer 120 is a third band offset; the band offset between the conduction band of the second barrier layer 120 and the conduction band of the compressive strained quantum well layer is a fourth band offset; and the ratio of the third band offset to the fourth band offset is in a range of 30/70 to 45/55.

If the band offset between the conduction band of the second barrier layer 120 and the conduction band of the compressive strained quantum well layer is too small, the degree to which the second barrier layer 120 can block conduction of electrons from the compressive strained quantum well layer to the second barrier layer 120 is weakened; if the band offset between the conduction band of the second barrier layer 120 and the conduction band of the compressive strained quantum well layer is too large, then the band gap of the second barrier layer 120 is too large, and the turn-on voltage is increased. In the present embodiment, the ratio of the third band offset to the fourth band offset is in a range of 30/70 to 45/55, taking into account the blocking of electron leakage and the lower turn-on voltage. In one embodiment, the ratio of the third band offset to the fourth band offset is 2:3.

The present embodiment focuses on the asymmetric first strained barrier layer 100 and second barrier layer 120. The benefits of the asymmetric first strained barrier layer 100 and second barrier layer 120 of the present embodiment will be described below in combination with Comparative Example 3 and Comparative Example 4.

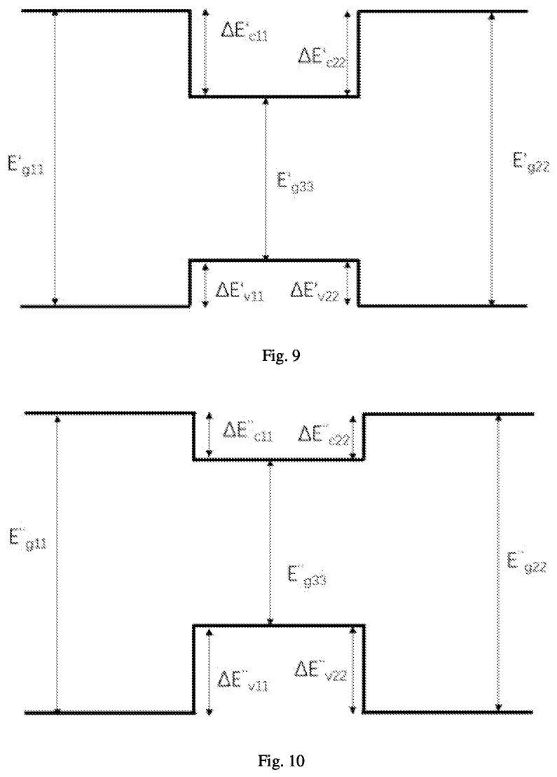

FIG. 9 is an energy band diagram of an active layer provided in Comparative Example 3, the active layer of Comparative Example 3 includes a first barrier layer, a second barrier layer and a quantum well layer, wherein the first barrier layer and the second barrier layer are located on both sides of the quantum well layer, and the materials of the first barrier layer and the second barrier layer are the same, the quantum well layer is tensile strained Inₓ₃Ga₁₋ₓ₃As, and the materials of the first barrier layer and the second barrier layer are all strain-free Alₓ₂Ga₁₋ₓ₂As.

In FIG. 9, E′_{g11} is the band gap of the first barrier layer in Comparative Example 3, E′_{g22} is the band gap of the second barrier layer in Comparative Example 3, E′_{g33} is the band gap of the quantum well layer in Comparative Example 3, and E′_{g22}=E′_{g11}=E_{g1}; ΔE′ᵥ₁₁ is the band offset between the valence band of the quantum well layer and the valence band of the first barrier layer in Comparative Example 3, ΔE′ᵥ₂₂ is the band offset between the valence band of the quantum well layer and the valence band of the second barrier layer in Comparative Example 3, ΔE′_{c11} is the band offset between the conduction band of the first barrier layer and the conduction band of the quantum well layer in Comparative Example 3, and ΔE′_{c22} is the band offset between the conduction band of the second barrier layer and the conduction band of the quantum well layer in Comparative Example 3.

FIG. 10 is an energy band diagram of an active layer provided in Comparative Example 4. The active layer of Comparative Example 4 includes a first barrier layer, a second barrier layer and a quantum well layer, wherein the first barrier layer and the second barrier layer are located on both sides of the quantum well layer, the materials of the first barrier layer and the second barrier layer are the same. The quantum well layer is tensile strained Inₓ₃Ga₁₋ₓ₃As, and the materials of the first barrier layer and the second barrier layer are compressive strained GaAsₓ₁P₁₋ₓ₁.

In FIG. 10, E″_{g11} is the band gap of the first barrier layer in Comparative Example 4, E″_{g22} is the band gap of the second barrier layer in Comparative Example 4, E″_{g33} is the band gap of the quantum well layer in Comparative Example 4, E″_{g22}=E″_{g11}=E_{g1}; ΔE″ᵥ₁₁ is the band offset between the valence band of the quantum well layer and the valence band of the first barrier layer in Comparative Example 4, ΔE″ᵥ₂₂ is the band offset between the valence band of the quantum well layer and the valence band of the second barrier layer in Comparative Example 4, ΔE″_{c11} is the band offset between the conduction band of the first barrier layer and the conduction band of the quantum well layer in Comparative Example 4, and ΔE″_{c22} is the band offset between the conduction band of the second barrier layer and the conduction band of the quantum well layer in Comparative Example 4.

In the present embodiment, the energy loss during injection of electrons and holes into the compressive strained quantum well layer is in direct proportion to the sum of the band offset between the conduction bands of the tensile strained barrier layer and the compressive strained quantum well layer and the band offset between the valence bands of the compressive strained quantum well layer and the second barrier layer.

In the present embodiment, ΔEₛ₁=a1*ΔE_{c1}+a2*ΔEᵥ₂, a1 and a2 are constant coefficients greater than 0, and ΔEₛ₁ is the energy loss during injection of electrons and holes into the compressive strained quantum well layer in the present embodiment. In Comparative Example 3, ΔE′ₛ₁=a1*ΔE′_{c1}1+a2*ΔE′ᵥ₂₂, a1 and a2 are constant coefficients greater than 0, and ΔE′ₛ₁ is the energy loss during injection of electrons and holes into the quantum well layer in Comparative Example 3. In Comparative Example 4, ΔE″ₛ₁=a1*ΔE″_{c11}+a2*ΔE″ᵥ₂₂, a1 and a2 are constant coefficients greater than 0, and ΔE″ₛ₁ is the energy loss during injection of electrons and holes into the quantum well layer in Comparative Example 4.

In the present embodiment, ΔE_{c1} is 0.4*ΔE_{g1}, and ΔEᵥ₂ is 0.4*ΔE_{g2}. ΔE_{g1}=E_{g1}-E_{g3}, ΔE_{g2}=E_{g2}-E_{g3}. Correspondingly, ΔEₛ₁=a1*0.4*ΔE_{g1}+a2*0.4*ΔE_{g2}.

In Comparative Example 3, ΔE′_{c11} is 0.6*ΔE′_{g11}, ΔE′ᵥ₂₂ is 0.4*ΔE′_{g22}. ΔE′_{g11}=E′_{g11}-E′_{g33}, and ΔE′_{g22}=E′_{g22}-E′_{g33}. Correspondingly, ΔE′ₛ₁=a1*0.6*ΔE′_{g11}+a2*0.4*ΔE′_{g22}. ΔE′_{g11}=ΔE′_{g22}.

In Comparative Example 4, ΔE″_{c11} is 0.4*ΔE″_{g11}, ΔE″ᵥ₂₂ is 0.6*ΔE″_{g22}. ΔE″_{g11}=E″_{g11}-E″_{g33}, ΔE″_{g22}=E″_{g22}-E″_{g33}. Correspondingly, ΔE″ₛ₁=a1*0.4*ΔE″_{g11}+a2*0.6*ΔE″_{g22}. ΔE″_{g11}=ΔE″_{g22}.

Since the material of the second barrier layer adopted in Comparative Example 3 is consistent with that of the present embodiment, the material of the quantum well layer adopted in Comparative Example 3 is consistent with the material of the compressive strained quantum well layer used in the present embodiment, so ΔE′_{g22}=ΔE_{g2}.

$$Δ {E}_{s 1} - Δ {{E}^{′}}_{s 1} = a 1 * 0.4 * Δ {E}_{g 1} + a 2 * 0.4 * Δ {E}_{g 2} - a 1 * 0.6 * Δ {{E}^{′}}_{g 11} - a 2 * 0.4 * Δ {{E}^{′}}_{g 22} = a 1 * 0.4 * Δ {E}_{g 1} - a 1 * 0.6 * Δ {{E}^{′}}_{g 11} = -- a 1 * 0.2 * Δ {E}_{g 1} < 0.$$

$$Therefore ,$$

$$Δ {E}_{s 1} < Δ {{E}^{′}}_{s 1} .$$

Since the first barrier layer adopted in Comparative Example 4 is consistent with the material of the first strained barrier layer adopted in the present embodiment, the material of the quantum well layer adopted in Comparative Example 4 is correspondingly consistent with the material of the compressive strained quantum well layer adopted in the present embodiment, so ΔE″_{g11}=ΔE_{g1}.

$$Δ {E}_{s 1} - Δ {{E}^{′}}_{s 1} = a 1 * 0.4 * Δ {E}_{g 1} + a 2 * 0.4 * Δ {E}_{g 2} - a 1 * 0.4 * Δ {{E}^{′′}}_{g 11} - a 2 * 0.6 * Δ {{E}^{′′}}_{g 22} = a 2 * 0.4 * Δ {E}_{g 2} - a 2 * 0.6 * Δ {{E}^{′′}}_{g 22} = - a 2 * 0.2 * Δ {E}_{g 2} < 0.$$

$$Therefore ,$$

$$Δ {E}_{s 1} < Δ {{E}^{′′}}_{s 1} .$$

According to the above analysis: in the present embodiment, the material of the compressive strained quantum well layer is Inₓ₆Ga₁₋ₓ₆As, the material of the first strained barrier layer is GaAsₓ₄P₁₋ₓ₄, and the band offset ΔE_{c1} between the conduction bands of the first strained barrier layer 100 and the compressive strained quantum well layer is small, which can reduce the energy loss during injection of electron carriers; at the same time, the material of the second barrier layer 120 is Alₓ₅Ga₁₋ₓ₅As, and the band offset ΔEᵥ₂ between the valence bands of the compressive strained quantum well layer and the second barrier layer 120 is small, which can reduce the energy loss during injection of hole carriers. The arrangement of the asymmetric first strained barrier layer 100 and the second barrier layer 120 enables the active layer to have the lowest energy loss during injection of carriers, that is, the largest energy quantum efficiency.

In the present embodiment, the proportion of carriers injected into the compressive strained quantum well layer and escaped is associated with its escape barrier. In the present embodiment, the ratio Se₁ of electrons escaping from the compressive strained quantum well layer is positively correlated with the band offset between the conduction bands of the compressive strained quantum well layer and the second barrier layer 120, that is, Se₁=d₁*exp(−ΔE_{c2}/k₀T), where k₀ is Boltzmann constant 1.380649×10₋₂₃J/K; T is the temperature (K) of the compressive strained quantum well layer. In the present embodiment, the ratio Sn₁ of holes escaping from the compressive strained quantum well layer is positively correlated with the band offset between the valence bands of the compressive strained quantum well layer and the first strained barrier layer, that is, Sn₁=d₂*exp(−ΔEᵥ₁/k₀T). d₁ is a coefficient of Se₁, and d₂ is a coefficient of Sn₁.

In Comparative Example 3, the ratio Se₁′ of electrons escaping from the quantum well layer is positively correlated with the band offset between the conduction bands of the quantum well layer and the second barrier layer, that is, Se₁′=d₁*exp(−ΔE′_{c22}/k₀T), the ratio Sn₁′ of the holes escaping from the quantum well layer is positively correlated with the band offset between the valence bands of the quantum well layer and the first barrier layer, Sn₁′=d₂*exp(−ΔE′ᵥ₁₁/k₀T). d₁ is the coefficient of Se₁′, d₂ is the coefficient of Sn₁′, and T is the temperature of the quantum well layer in Comparative Example 3.

In Comparative Example 4, the ratio Se₁″ of electrons escaping from the quantum well layer is positively correlated with the band offset between the conduction bands of the quantum well layer and the second barrier layer, that is, Se₁″=d₁*exp(−ΔE″_{c22}/k₀T), the ratio Sn₁″ of holes escaping from the quantum well layer is positively correlated with the band offset between the valence bands of the quantum well layer and the first barrier layer, Sn₁″=d₂*exp(−ΔE″ᵥ₁₁/k₀T). d₁ is the coefficient of Se₁″, d₂ is the coefficient of Sn₁″, and T is the temperature of the quantum well layer.

In the present embodiment, the relationship between the quantum efficiency η1 of the high-efficiency active layer of 870 nm to 1100 nm and the escape ratio is as follows:

$$η 1 = ( 1 - {d}_{1} exp ( - \frac{Δ {E}_{{C}_{2}}}{{k}_{0} T} ) ) * ( 1 - {d}_{2} exp ( - \frac{Δ {E}_{{V}_{1}}}{{k}_{0} T} ) ) .$$

In Comparative Example 3, the relationship between the quantum efficiency η1′ of the active layer and the escape ratio is as follows:

$${η1}^{′} = ( 1 - {d}_{1} exp ( - \frac{Δ E {′}_{{C}_{22}}}{{k}_{0} T} ) ) * ( 1 - {d}_{2} exp ( - \frac{Δ E {′}_{{V}_{11}}}{{k}_{0} T} ) ) .$$

In Comparative Example 4, the relationship between the quantum efficiency η′ of the active layer and the escape ratio is as follows:

$${η1}^{′′} = ( 1 - {d}_{1} exp ( - \frac{Δ E {′′}_{{C}_{2}}}{{k}_{0} T} ) ) * ( 1 - {d}_{2} exp ( - \frac{Δ E {′′}_{{V}_{1}}}{{k}_{0} T} ) )$$

$$\frac{η1}{η1′} = ( 1 - {d}_{2} exp ( - \frac{Δ {E}_{V 1}}{{k}_{0} T} ) ) / ( 1 - {b}_{2} exp ( - \frac{Δ E {′}_{V 11}}{{k}_{0} T} ) ) = ( 1 - {d}_{2} exp ( - \frac{0.6 * Δ Eg 1}{{k}_{0} T} ) ) / ( 1 - {d}_{2} exp ( - \frac{0.4 * Δ {E}^{′} g 11}{{k}_{0} T} ) ) > 1$$

$$\frac{η1}{η1″} ( 1 - {d}_{1} exp ( - \frac{Δ {E}_{{C}_{2}}}{{k}_{0} T} ) ) / ( 1 - {d}_{1} exp ( - \frac{Δ E {″}_{{C}_{2}}}{{k}_{0} T} ) ) = ( 1 - {d}_{1} exp ( - \frac{0.6 * Δ Eg 2}{{k}_{0} T} ) ) / ( 1 - {d}_{1} exp ( - \frac{0.4 * Δ {E}^{″} g 22}{{k}_{0} T} ) ) > 1.$$

$$Therefore ,$$

$$η1 > {η1}^{′} ,$$

$$η1 > {η1}^{′′} .$$

According to the above analysis, in the present embodiment, the material of the compressive strained quantum well layer is Inₓ₆Ga₁₋ₓ₆As, the material of the first strained barrier layer 100 is GaAsₓ₄P₁₋ₓ₄, and the band offset ΔEᵥ₁ between the valence bands of the compressive strained quantum well layer and the first strained barrier layer 100 is larger; the ability of blocking hole carriers by the first strained barrier layer 100 is enhanced, to better block holes transferred from the compressive strained quantum well layer to the first strained barrier layer 100 on the valence band, such that the holes are better confined in a potential well of the compressive strained quantum well layer. At the same time, the material of the second barrier layer 120 is Alₓ₅Ga₁₋ₓ₅As. The band offset ΔE_{c2} between the conduction bands of the compressive strained quantum well layer and the second barrier layer 120 is larger, the ability of blocking electrons by the second barrier layer 120 is enhanced, to better block electrons transferred from the compressive strained quantum well layer to the second strained barrier layer 120 on the conduction band, such that the electrons are better confined in a potential well of the compressive strained quantum well layer.

In the present embodiment, unsymmetrical first strained barrier layer and second barrier layer are adopted, which is beneficial for reducing the turn-on voltage of the high-efficiency active layer with a luminous wavelength of 870 nm to 1100 nm and further improving the light-emitting efficiency.

In the present embodiment, the turn-on voltage is in direct proportion to the sum of the band gap of the compressive strained quantum well layer, the band offset between the conduction bands of the tensile strained barrier layer and the compressive strained quantum well layer and the band offset between the valence bands of the compressive strained quantum well layer and the second barrier layer.

In the present embodiment, the third voltage V₃₁ which is associated with the band gap of the compressive strained quantum well layer is equal to E_{g3}/e, wherein e is an electron charge; the voltage positively correlated with the band offset ΔE_{c1} between the conduction bands of the tensile strained barrier layer and the compressive strained quantum well layer is the first voltage drop V₁₁, V₁₁=q1*ΔE_{c1}, q1>0; the voltage positively correlated with the band offset ΔEᵥ₂ between the valence bands of the compressive strained quantum well layer and the second barrier layer is the second voltage drop V₂₁, V₂₁=q2*ΔEᵥ₂, q2>0; the turn-on voltage is as follows:

$$Δ {V}_{F} = {V}_{1} + {V}_{2} + {V}_{3} = q 1 * Δ {E}_{c 1} + q 2 * Δ {E}_{v 2} + {E}_{g 3} / e = q 1 * 0.4 * Δ {E}_{g 1} + q 2 * 0.4 * Δ {E}_{g 2} + {E}_{g 3} / e .$$

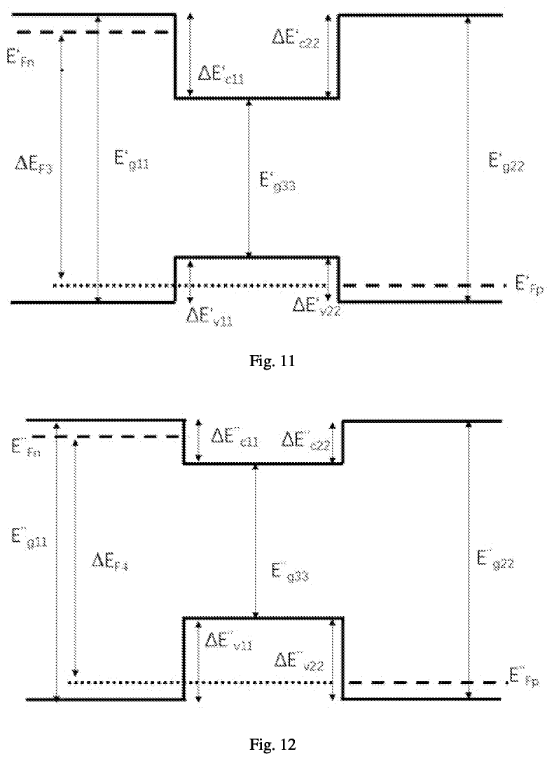

Please refer to FIG. 11, in Comparative Example 3, a third voltage V′₃₁ which is associated with the band gap of the quantum well layer is equal to E′_{g33}/e, wherein e is an electron charge; the voltage positively correlated with the band offset ΔE′_{c11} between the conduction bands of the first barrier layer and the quantum well layer is V′₁₁; V′₁₁=q1*ΔE′_{c11}, q1>0; the voltage positively correlated with the band offset ΔE′ᵥ₂₂ between the valence bands of the quantum well layer and the second barrier layer is the second voltage drop V′₂₁, V′₂₁=q2*ΔE′ᵥ₂₂, q2>0; the turn-one voltage is as follows: ΔV_{F3}=V′₁₁+V′₂₁+V′₃₁=q1*ΔE′_{c11}+q2*ΔE′ᵥ₂₂+E′_{g33}/e=q1*0.6*ΔE′_{g11}+q2*0.4*ΔE′_{g22}+E′_{g 33}/e. ΔV_{F3} corresponds to ΔE_{F3}.

Please refer to FIG. 12, in Comparative Example 4, the third voltage V″₃₁ which is associated with the band gap of the quantum well layer is equal to E″_{g33}/e, wherein e is an electron charge; the voltage positively correlated with the band offset ΔE″_{c11} between the conduction bands of the first barrier layer and the quantum well layer is the first voltage drop V″₁₁, V″₁₁=q1*ΔE″_{c11}, q1>0; the voltage positively correlated with the band offset ΔE″ᵥ₂₂ between the valence bands of the quantum well layer and the second barrier layer is the second voltage drop V″₂₁, V″₂₁=q2*ΔE″ᵥ₂₂, q2>0; the turn-on voltage is as follows: ΔV_{F4}=V″₁₁+V″₂₁+V″₃₁=q1*ΔE″_{c11}+q2*ΔE″ᵥ₂₂+E″_{g33}/e=q1*0.4*ΔE″_{g11}+q2*0.6*ΔE″_{g22}+E″_{g33}/e. ΔV_{F4} corresponds to ΔE_{F4}.

$$Δ {V}_{F} - Δ {V}_{F 3} = q 1 * 0.4 * Δ {E}_{g 1} + q 2 * 0.4 * Δ {E}_{g 2} + {E}_{g 3} / e - ( q 1 * 0.6 * Δ {{E}^{′}}_{g 11} + q 2 * 0.4 * Δ {{E}^{′}}_{g 22} + Δ {{E}^{′}}_{g 33} / e ) = q 1 * 0.4 * Δ {E}_{g 1} - q 1 * 0.6 * Δ {{E}^{′}}_{g 11} = - q 1 * 0.2 * Δ {E}_{g 1} / e < 0.$$

$$Δ {V}_{F} < Δ {V}_{F 3} .$$

$$Δ {V}_{F} - Δ {V}_{F 4} = q 1 * 0.4 * Δ {E}_{g 1} + q 2 * 0.4 * Δ {E}_{g 2} + {E}_{g 3} / e - ( q 1 * 0.4 * Δ {{E}^{′′}}_{g 11} + q 2 * 0.6 * Δ {{E}^{′′}}_{g 22} + Δ {{E}^{′′}}_{g 33} / e ) = q 2 * 0.4 * Δ {E}_{g 2} - q 2 * 0.6 * Δ {{E}^{′′}}_{g 22} = - q 2 * 0.2 * Δ {E}_{g 2} / e < 0.$$

$$Δ {V}_{F} < Δ {V}_{F 4} .$$

In the present embodiment, a smaller band offset between the conduction bands of the tensile strained barrier layer and the compressive strained quantum well layer and a smaller band offset between the valence bands of the compressive strained quantum well layer and the second barrier layer can be obtained simultaneously, and the turn-on voltage of a PN junction can be reduced.

In the prior art, the quantum well layer adopted by the active layer in a luminous waveband of 870 nm to 1100 nm is an Al-containing structure, the content of Al is high, and Al is easy to oxidize and easy to produce defects in the material, nonradiative recombination is increased, therefore, on the one hand, the performance is reduced, and on the other hand, the reliability is reduced.

In the present embodiment, the material of the compressive strained quantum well layer does not contain Al, thereby avoiding oxidation of the material in the compressive strained quantum well layer and avoiding generating defects, avoiding an increase of nonradiative recombination, and improving the reliability of the compressive strained quantum well layer.

### Embodiment 4

The present embodiment provides a semiconductor light-emitting device, including a high-efficiency active layer of Embodiment 1, Embodiment 2 or Embodiment 3.

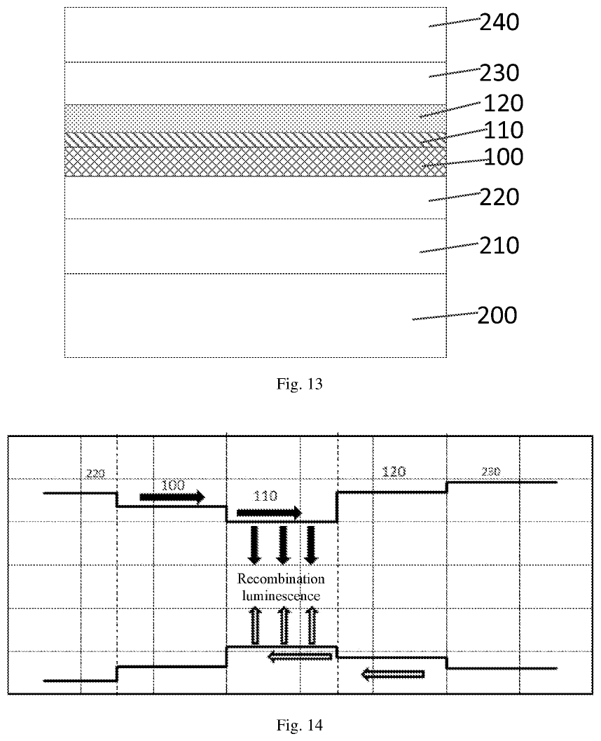

Please refer to FIG. 13, a semiconductor light-emitting device being an edge-emitting semiconductor laser is taken as an example for illustration. The semiconductor light-emitting device includes: a semiconductor substrate layer 200; an N-type waveguide layer 220 and a P-type waveguide layer 230 arranged relatively on the semiconductor substrate layer 200, wherein a high-efficiency active layer is located between the N-type waveguide layer 220 and the P-type waveguide layer 230; an N-type limiting layer 210 and a P-type limiting layer 240, wherein the N-type limiting layer 210 is located on a side, away from the high-efficiency active layer, of the N-type waveguide layer 220, and the P-type limiting layer 240 is located on a side, away from the high-efficiency active layer, of the P-type waveguide layer 230.

In the present embodiment, the material of the semiconductor substrate layer 200 includes gallium arsenide (GaAs); in other embodiments, the material of the semiconductor substrate layer 200 may also be other materials.

The high-efficiency active layer includes a first strained barrier layer 100, a second barrier layer 120 and a strained quantum well layer 110. For the high-efficiency active layer in the present embodiment, please refer to the high-efficiency active layer of Embodiment 1.

In one embodiment, the material of the strained quantum well layer 110 is tensilely strained relative to the material of the semiconductor substrate layer 200, and the material of the first strained barrier layer 100 is compressively strained relative to the material of the semiconductor substrate layer 200. In another embodiment, the material of the strained quantum well layer 110 is compressively strained relative to the material of the semiconductor substrate layer 200, and the material of the first strained barrier layer 100 is tensilely strained relative to the material of the semiconductor substrate layer 200.

In one embodiment, the material of the second barrier layer 120 is strain-free relative to the material of the semiconductor substrate layer 200.

The material of the N-type waveguide layer 220 includes AlInGaP, and the material of the P-type waveguide layer 230 includes AlGaAs.

Please refer to FIG. 14, FIG. 14 is an energy band diagram of the device corresponding to FIG. 13. In FIG. 14, the energy bands of the N-type waveguide layer 220, the first strained barrier layer 100, the strained quantum well layer 1102, the second barrier layer 120 and the P-type waveguide layer 230 are sequentially from left to right.

### Embodiment 5

The present embodiment further defines the high-efficiency active layer as the high-efficiency active layer in Embodiment 2 on the basis of Embodiment 4.

When the luminous waveband of the semiconductor light-emitting device is in a range of 750 nm to 860 nm, the semiconductor light-emitting device can be used in semiconductor lasers with a waveband of 808 nm, 790 nm, 780 nm or 760 nm, and can be used for solid-state Nd-YAG crystal pumped lasers, alkali metal pumped lasers and medical lasers. This waveband requires higher efficiency and higher reliability.

The Comparative Example 5 provides a semiconductor light-emitting structure, including: a semiconductor substrate layer, an N-type limiting layer, an N-type waveguide layer, an active layer; wherein the active layer is the active layer in Comparative Example 1; a P-type waveguide layer, and a P-type limiting layer. The semiconductor substrate layer, the N-type waveguide layer, the P-type waveguide layer and the P-type limiting layer in Comparative Example 5 correspond to the semiconductor substrate layer, the N-type waveguide layer, the P-type waveguide layer, and the P-type limiting layer in the present embodiment.

FIG. 16 is a hole concentration distribution diagram in the semiconductor light-emitting device in the present embodiment and the semiconductor light-emitting structure in Comparative Example 5. It can be known from FIG. 16 that the hole concentration in the first strained barrier layer in the present embodiment is obviously reduced.

### Embodiment 6

The present embodiment further defines the high-efficiency active layer as the high-efficiency active layer in Embodiment 3 on the basis of Embodiment 4.

When the luminous waveband of the semiconductor light-emitting device is in a range of 870 nm to 1100 nm, the semiconductor light-emitting device can be used in semiconductor lasers with a waveband of 905 nm, 915 nm, 940 nm or 976 nm, for example, a semiconductor laser of 905 nm can be used for LIDAR, a semiconductor laser of 915 nm or 976 nm can be used for fiber laser pumped lasers, and a semiconductor laser of 940 nm can be used for solid-state Nd-YAG crystal pumped lasers. This waveband requires higher efficiency and higher reliability.

The Comparative Example 6 provides a semiconductor light-emitting structure, including: a semiconductor substrate layer, an N-type limiting layer, an N-type waveguide layer, an active layer; wherein the active layer is the active layer in Comparative Example 2; a P-type waveguide layer, and a P-type limiting layer. The semiconductor substrate layer, the N-type waveguide layer, the P-type waveguide layer and the P-type limiting layer in Comparative Example 6 are correspondingly consistent with the semiconductor substrate layer, the N-type waveguide layer, the P-type waveguide layer, and the P-type limiting layer in the present embodiment.

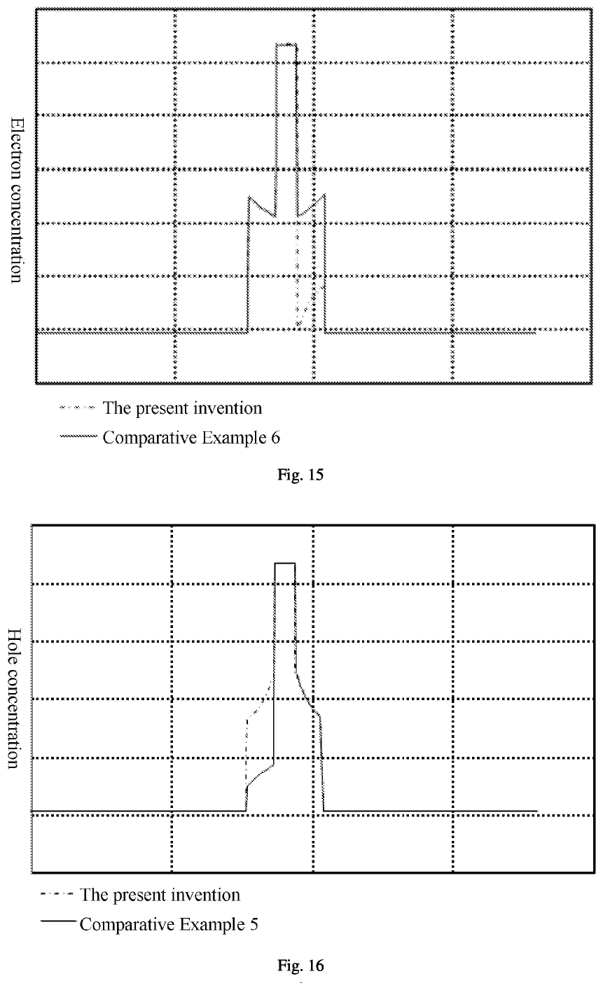

FIG. 15 is an electron concentration distribution diagram in the semiconductor light-emitting device in the present embodiment and the semiconductor light-emitting structure in Comparative Example 6. It can be known from FIG. 15 that the electron concentration in the second strained barrier layer in the present embodiment is obviously reduced.

### Embodiment 7

The present embodiment provides a method for manufacturing a high-efficiency active layer, including:

S1: forming a first strained barrier layer, wherein the first strained barrier layer is configured to transport electrons;

S2: forming a second barrier layer, wherein the second barrier layer is configured to transport holes; and

S3: forming a strained quantum well layer between the step of forming the first strained barrier layer and the step of forming the second barrier layer, wherein the first strained barrier layer and the strained quantum well layer are configured to form strain compensation; wherein the band offset between the conduction band of the first strained barrier layer and the conduction band of the strained quantum well layer is less than the band offset between the valence band of the strained quantum well layer and the valence band of the first strained barrier layer, and the band offset between the valence band of the strained quantum well layer and the valence band of the second barrier layer is less than the band offset between the conduction band of the second barrier layer and the conduction band of the strained quantum well layer.

The strained quantum well layer is formed after the first strained barrier layer is formed; and the second barrier layer is formed after the strained quantum well layer is formed. In another embodiment, the strained quantum well layer is formed after the second strained barrier layer is formed; and the first strained barrier layer is formed after the strained quantum well layer is formed.

For the description of the high-efficiency active layer of the present embodiment, please refer to the high-efficiency active layer of Embodiment 1.

### Embodiment 8

In the present embodiment, a luminous wavelength of the high-efficiency active layer is in a range of 750 nm to 860 nm; and the strained quantum well layer is a tensile strained quantum well layer, and the first strained barrier layer is a compressive strained barrier layer; the material of the tensile strained quantum well layer includes GaAsₓ₃P₁₋ₓ₃; the material of the compressive strained barrier layer includes Inₓ₁Ga₁₋ₓ₁P; and the material of the second barrier layer includes Alₓ₂Ga₁₋ₓ₂As.

In one embodiment, the strained quantum well layer is formed after the first strained barrier layer is formed; in the step of forming the first strained barrier layer, the In-source gas, the Ga-source gas and the P-source gas are introduced; in the step of forming the strained quantum well layer, the In-source gas is turned off, the Ga-source gas, the As-source gas and the P-source gas are introduced; and between the step of forming the first strained barrier layer and the step of forming the strained quantum well layer, first interruption processing, second interruption processing and third interruption processing are sequentially performed; during the first interruption processing, the In-source gas, the Ga-source gas and the As-source gas are turned off and the P-source gas is introduced; and during the second interruption processing, the In-source gas and the Ga-source gas are turned off, and the As-source gas and the P-source gas are introduced; and during the third interruption processing, the In-source gas and the Ga-source gas are turned off, the As-source gas and the P-source gas are introduced, a supplying amount of the P-source gas decreases with time during the third interruption processing. In the growth process of the third strained barrier layer, and during the first interruption processing, the second interruption processing, the third interruption processing and the growth process of the strained quantum well layer, the Al-source gas is turned off.

During the first interruption processing, the second interruption processing and the third interruption processing, all the elements of three groups are turned off, such that no film layer is grown during the first interruption processing, the second interruption processing and the third interruption processing, neither Inₓ₁Ga₁₋ₓ₁P nor GaAsₓ₃P₁₋ₓ₃ is grown. The P-source gas is introduced during the first interruption processing, and the P-source gas protects Inₓ₁Ga₁₋ₓ₁P, thereby avoiding a reverse reaction of the already grown Inₓ₁Ga₁₋ₓ₁P, and the P-source gas during the first interruption processing can blow away the remaining In-source gas and Ga-source gas in the chamber. During the second interruption processing, the As-source gas is introduced to prepare for the growth of the strained quantum well layer, and the flow rate of the As-source gas is regulated stably during the second interruption processing. The flow rate of the P-source gas during the third interruption processing decreases with time, in order to meet the flow rate demand of the P-source gas in the growth process of the strained quantum well layer. In a switching process between the third interruption processing and the growth process of the strained quantum well layer, only the Ga-source gas is turned on. Before the growth of the strained quantum well layer, both the P-source gas and the As-source gas are regulated stably, in the growth of the strained quantum well layer, the P-source gas and the As-source gas do not need to be regulated. To sum up, the steepness of the interface between the first strained barrier layer and the strained quantum well layer is improved.

During the first interruption processing, the flow rate of the P-source gas is constant; during the second interruption processing, the flow rate of the As-source gas is constant, and the flow rate of the P-source gas is constant. The flow rate of the P-source gas during the first interruption processing is equal to the flow rate of the P-source gas during the second interruption processing. The flow rate of the As-source gas during the third interruption processing is constant, and the flow rate of the P-source gas at the start time of the third interruption processing is equal to the flow rate of the P-source gas during the second interruption processing. The flow rate of the P-source gas at the end time of the third interruption processing is equal to the flow rate of the P-source gas during the growth of the strained quantum well layer, and the flow rate of the As-source gas at the end time of the third interruption processing is equal to the flow rate of the As-source gas during the growth of the strained quantum well layer. The growth temperature of the first strained barrier layer, the temperature of the first interruption processing, the temperature of the second interruption processing, the temperature of the third interruption processing are equal to the growth temperature of the strained quantum well layer.

In one embodiment the time of the third interruption processing is less than the time of the second interruption processing, and the time of the third interruption processing is less than the time of the first interruption processing. The time of the first interruption processing is in a range of 0.5 second to 10 seconds, the time of the second interruption processing is in a range of 0.5 second to 10 seconds, and the time of the third interruption processing is in a range of 0.5 second to 10 seconds.

In one embodiment, the second barrier layer is formed after the strained quantum well layer is formed; in the step of forming the strained quantum well layer, the In-source gas is turned off and the Ga-source gas, the As-source gas and the P-source gas are introduced; in the step of forming the second barrier layer, an Al-source gas, the Ga-source gas and the As-source gas are introduced, and the P-source gas is turned off; a fourth interruption processing is performed between the step of forming the strained quantum well layer and the step of forming the second barrier layer; and in the fourth interruption processing, the Ga-source gas and the P-source gas are turned off, and the As-source gas is introduced.

In the fourth interruption processing, the Al-source gas and the In-source gas are turned off. The As-source gas in the fourth interruption processing protects the already grown material of the strained quantum well layer, to avoid from a reverse reaction of the already grown strained quantum well layer, and the As-source gas in the fourth interruption processing blows away the remaining P-source gas in the chamber. In the fourth interruption processing, the gas of elements of three groups is turned off, so as to avoid formation of other impurity films. To sum up, the steepness of the interface between the strained quantum well layer and the second barrier layer is improved.

In the present embodiment, the growth temperature of the second barrier layer is greater than greater than the growth temperature of the strained quantum well layer. The temperature in the fourth interruption processing increases with time. The temperature at the end time of the fourth interruption processing is equal to the growth temperature of the second barrier layer. The temperature at the start time of the fourth interruption processing is equal to the temperature of the first strained barrier layer.

In one embodiment, the time of the second interruption processing is in a range of 0.5 second to 10 seconds.

In the present embodiment, the Al-source gas includes trimethyl aluminum, the In-source gas includes trimethyl indium, the Ga-source gas includes trimethyl gallium, the As-source gas includes arsine, and the P-source gas includes phosphine.

### Embodiment 9

In the present embodiment, a luminous wavelength of the high-efficiency active layer is in a range of 870 nm to 1100 nm; and the strained quantum well layer is a compressive strained quantum well layer, and the first strained barrier layer is a tensile strained barrier layer; the material of the compressive strained quantum well layer includes Inₓ₆Ga₁₋ₓ₆As; the material of the tensile strained barrier layer includes GaAsₓ₄P₁₋ₓ₄; and the material of the second barrier layer includes Alₓ₅Ga₁₋ₓ₅As.

In one embodiment, the strained quantum well layer is formed after the first strained barrier layer is formed; in the step of forming the first strained barrier layer, the Ga-source gas, the As-source gas and the P-source gas are introduced; in the step of forming the strained quantum well layer, the In-source gas, the Ga-source gas and the As-source gas are introduced; and between the step of forming the first strained barrier layer and the step of forming the strained quantum well layer, first interruption processing and second interruption processing are sequentially performed; during the first interruption processing, the Ga-source gas is turned off and the As-source gas and the P-source gas are introduced; and during the second interruption processing, the Ga-source gas is turned off, and the As-source gas and the P-source gas are introduced; and a supplying amount of the P-source gas decreases with time during the second interruption processing, and a supplying amount of the As-source gas increases with time during the second interruption processing.

In the growth process of the first strained barrier layer, and during the first interruption processing, the second interruption processing, and the growth process of the strained quantum well layer, the Al-source gas is turned off. During the first interruption processing, the In-source gas is turned off. During the second interruption processing, the In-source gas is turned off. In the step of forming the strained quantum well layer, the P-source gas is turned off.

During the first interruption processing and the second interruption processing, all the elements of three groups are turned off, such that no film layer is grown during the first interruption processing and the second interruption processing, neither GaAsₓ₄P₁₋ₓ₄ nor Inₓ₆Ga₁₋ₓ₆As is grown. The As-source gas and the P-source gas are introduced during the first interruption processing, and the As-source gas and the P-source gas protect GaAsₓ₄P₁₋ₓ₄, thereby avoiding a reverse reaction of the already grown GaAsₓ₄P₁₋ₓ₄. During the second interruption processing, the As-source gas and the P-source gas are introduced, a supplying amount of the P-source gas decreases with time during the second interruption processing, a supplying amount of the As-source gas increases with time during the second interruption processing, and the flow rate of the As-source gas is regulated stably during the second interruption processing, to prepare for the growth of the strained quantum well layer, in order to meet the flow rate demand of the As-source gas in the growth process of the strained quantum well layer. To sum up, the steepness of the interface between the first strained barrier layer and the strained quantum well layer is improved.

During the first interruption processing, the flow rate of the P-source gas is constant, and the flow rate of the As-source gas is constant. The flow rate of the P-source gas at the start time of the second interruption processing is equal to the flow rate of the P-source gas during the first interruption processing. The flow rate of the P-source gas at the end time of the second interruption processing is zero. The flow rate of the As-source gas at the start time of the second interruption processing is equal to the flow rate of the As-source gas during the first interruption processing. The flow rate of the As-source gas at the end time of the second interruption processing is equal to the flow rate of the As-source gas in the growth process of the strained quantum well layer. The growth temperature for forming the strained quantum well layer is lower than the growth temperature for forming the first strained barrier layer and is lower than the temperature during the first interruption processing; the growth temperature for forming the strained quantum well layer is constant during the step of forming the strained quantum well layer, the growth temperature for forming the first strained barrier layer is constant during the step of forming the first strained barrier layer, and the temperature during the first interruption processing is constant; the temperature during the second interruption processing is greater than greater than the growth temperature for forming the strained quantum well layer and is lower than the temperature of the first interruption processing, and the temperature during the second interruption processing decreases with time.

In one embodiment, the time of the first interruption processing is in a range of 0.5 second to 10 seconds, and the time of the second interruption processing is in a range of 0.5 second to 10 seconds.

In one embodiment, the second barrier layer is formed after the strained quantum well layer is formed; in the step of forming the strained quantum well layer, the In-source gas, the Ga-source gas and the As-source gas are introduced; in the step of forming the second barrier layer, an Al-source gas, the Ga-source gas and the As-source gas are introduced; between the step of forming the strained quantum well layer and the step of forming the second barrier layer, the third interruption processing is performed; during the third interruption processing, the In-source gas and the Ga-source gas are turned off, and the As-source gas is introduced.

During the third interruption processing, the Al-source gas and the P-source gas are turned off.

The As-source gas during the third interruption processing protects the already grown material of the strained quantum well layer, to avoid from a reverse reaction of the already grown strained quantum well layer, and the As-source gas during the third interruption processing blows away the remaining In-source gas in the chamber. In the fourth interruption processing, the gas of elements of three groups is turned off, so as to avoid formation of other impurity films. To sum up, the steepness of the interface between the strained quantum well layer and the second barrier layer is improved.

The growth temperature for forming the strained quantum well layer is lower than the growth temperature for forming the second barrier layer; the growth temperature for forming the strained quantum well layer is constant during the step of forming the strained quantum well layer, and the growth temperature for forming the second barrier layer is constant during the step of forming the second strained barrier layer; the temperature during the third interruption processing is greater than greater than the growth temperature for forming the strained quantum well layer and is less than the growth temperature for forming the second barrier layer, and the temperature during the third interruption processing increases with time.

In one embodiment, the time of the third interruption processing is in a range of 0.5 second to 10 seconds.

In the present embodiment, the Al-source gas includes trimethyl aluminum, the In-source gas includes trimethyl indium, the Ga-source gas includes trimethyl gallium, the As-source gas includes arsine, and the P-source gas includes phosphine.

### Embodiment 10

The present embodiment provides a method for manufacturing a semiconductor light-emitting device, including the method for manufacturing the high-efficiency active layer of Embodiment 7, Embodiment 8 or Embodiment 9.

The method for manufacturing the semiconductor light-emitting device further includes: providing a semiconductor substrate layer; the step of forming a first strained barrier layer is performed by forming a first strained barrier layer on the semiconductor substrate layer; the step of forming a second barrier layer is performed by forming a second barrier layer on the semiconductor substrate layer; the material of the strained quantum well layer is tensilely strained relative to the material of the semiconductor substrate layer, and the material of the first strained barrier layer is compressively strained relative to the material of the semiconductor substrate layer; or the material of the strained quantum well layer is compressively strained relative to the material of the semiconductor substrate layer, and the material of the first strained barrier layer is tensilely strained relative to the material of the semiconductor substrate layer.

In the present embodiment, a strained quantum well layer being formed after the first strained barrier layer is formed and then a second barrier layer being forming is taken as an example. The semiconductor light-emitting device is an edge-emitting semiconductor laser. Correspondingly, the method for manufacturing the semiconductor light-emitting device further includes the following steps: forming an N-type limiting layer on the semiconductor substrate layer; forming an N-type waveguide layer on the N-type limiting layer; forming a high-efficiency active layer after forming an N-type waveguide layer; then forming a P-type waveguide layer; and then forming a P-type limiting layer.

Apparently, the above-described embodiments are merely illustrative for clarity and are not for a limitation to implementation. For those skilled in the art, other variations or alterations in different forms may be made on the basis of the above description. All the implementations do not need to be and cannot be enumerated herein, and the apparent variations or alterations arising therefrom still fall within the protection scope of the present application.

1. A high-efficiency active layer, comprising:
a strained quantum well layer;
a first strained barrier layer located on one side of the strained quantum well layer, wherein the first strained barrier layer is configured to transport electrons; and the first strained barrier layer and the strained quantum well layer are configured to form strain compensation;
a second barrier layer located on the other side of the strained quantum well layer, wherein the second barrier layer is configured to transport holes;
wherein a band offset between a conduction band of the first strained barrier layer and a conduction band of the strained quantum well layer is less than a band offset between a valence band of the strained quantum well layer and a valence band of the first strained barrier layer, and a band offset between a valence band of the strained quantum well layer and a valence band of the second barrier layer is less than a band offset between a conduction band of the second barrier layer and a conduction band of the strained quantum well layer.

2. The high-efficiency active layer of claim 1, wherein:
the band offset between the conduction band of the first strained barrier layer and the conduction band of the strained quantum well layer is less than the band offset between the conduction band of the second barrier layer and the conduction band of the strained quantum well layer; and
the band offset between the valence band of the strained quantum well layer and the valence band of the second barrier layer is less than the band offset between the valence band of the strained quantum well layer and the valence band of the first strained barrier layer.

3. The high-efficiency active layer of claim 1, wherein a band gap of the first strained barrier layer is equal to a band gap of the second barrier layer.

4. The high-efficiency active layer of claim 1, wherein:
a luminous wavelength of the high-efficiency active layer is in a range of 750 nm to 860 nm; and
the strained quantum well layer is a tensile strained quantum well layer, and the first strained barrier layer is a compressive strained barrier layer; the material of the tensile strained quantum well layer comprises GaAsₓ₃P₁₋ₓ₃; the material of the compressive strained barrier layer comprises Inₓ₁Ga₁₋ₓ₁P; and the material of the second barrier layer comprises Alₓ₂Ga₁₋ₓ₂As.

5. The high-efficiency active layer of claim 4, wherein:
a band offset between a conduction band of the compressive strained barrier layer and a conduction band of the tensile strained quantum well layer is a first band offset;
a band offset between a valence band of the tensile strained quantum well layer and a valence band of the compressive strained barrier layer is a second band offset; and
a ratio of the first band offset to the second band offset is in a range of 35/65 to 47/53.

6. The high-efficiency active layer of claim 4, wherein;
a band offset between the valence band of the tensile strained quantum well layer and the valence band of the second barrier layer is a third band offset;
a band offset between the conduction band of the second barrier layer and the conduction band of the tensile strained quantum well layer is a fourth band offset; and
a ratio of the third band offset to the fourth band offset is in a range of 35/65 to 47/53.

7. The high-efficiency active layer of claim 4, wherein the thickness of the tensile strained quantum well layer is in a range of 8 nm to 20 nm.

8. The high-efficiency active layer of claim 4, wherein x3 ranges from 0.70 to 0.95.

9. The high-efficiency active layer of claim 8, wherein the material of the tensile strained quantum well layer is GaAs_{0.82}P_{0.18}.

10. The high-efficiency active layer of claim 1, wherein;
a luminous wavelength of the high-efficiency active layer is in a range of 870 nm to 1100 nm;
the strained quantum well layer is a compressive strained quantum well layer, and the first strained barrier layer is a tensile strained barrier layer;
the material of the compressive strained quantum well layer comprises Inₓ₆Ga₁₋ₓ₆As;
the material of the tensile strained barrier layer comprises GaAsₓ₄P₁₋ₓ₄; and
the material of the second barrier layer comprises Alₓ₅Ga₁₋ₓ₅As.

11. The high-efficiency active layer of claim 10, wherein:
a band offset between a conduction band of the tensile strained barrier layer and a conduction band of the compressive strained quantum well layer is a first band offset;
a band offset between a valence band of the compressive strained quantum well layer and a valence band of the tensile strained barrier layer is a second band offset; and
a ratio of the first band offset to the second band offset is in a range of 30/70 to 45/55.

12. The high-efficiency active layer of claim 10, wherein:
a band offset between the valence band of the compressive strained quantum well layer and the valence band of the second barrier layer is a third band offset;
a band offset between the conduction band of the second barrier layer and the conduction band of the compressive strained quantum well layer is a fourth band offset; and
a ratio of the third band offset to the fourth band offset is in a range of 30/70 to 45/55.

13.-16. (canceled)

17. A semiconductor light-emitting device, comprising the high-efficiency active layer of claim 1.

18. The semiconductor light-emitting device of claim 17, further comprising a semiconductor substrate layer, wherein:
the high-efficiency active layer is located on the semiconductor substrate layer; and
the material of the strained quantum well layer is tensilely strained relative to the material of the semiconductor substrate layer, and the material of the first strained barrier layer is compressively strained relative to the material of the semiconductor substrate layer; or, alternatively, the material of the strained quantum well layer is compressively strained relative to the material of the semiconductor substrate layer, and the material of the first strained barrier layer is tensilely strained relative to the material of the semiconductor substrate layer.

19. The semiconductor light-emitting device of claim 17, further comprising:
an N-type waveguide layer and a P-type waveguide layer arranged opposite to each other, wherein the high-efficiency active layer is located between the N-type waveguide layer and the P-type waveguide layer; and
an N-type limiting layer and a P-type limiting layer, wherein:
the N-type limiting layer is located on a side, away from the high-efficiency active layer, of the N-type waveguide layer, and
the P-type limiting layer is located on a side, away from the high-efficiency active layer, of the P-type waveguide layer.

20. A method for manufacturing the high-efficiency active layer of claim 1, comprising:
forming a first strained barrier layer, wherein the first strained barrier layer is configured to transport electrons;
forming a second barrier layer, wherein the second barrier layer is configured to transport holes; and
forming a strained quantum well layer between the step of forming the first strained barrier layer and the step of forming the second barrier layer, wherein the first strained barrier layer and the strained quantum well layer are configured to form strain compensation; wherein
a band offset between the conduction band of the first strained barrier layer and the conduction band of the strained quantum well layer is less than a band offset between the valence band of the strained quantum well layer and the valence band of the first strained barrier layer, and a band offset between the valence band of the strained quantum well layer and the valence band of the second barrier layer is less than a band offset between the conduction band of the second barrier layer and the conduction band of the strained quantum well layer.

21. The method of claim 20 for manufacturing the high-efficiency active layer, wherein:
a luminous wavelength of the high-efficiency active layer is in a range of 750 nm to 860 nm;
the strained quantum well layer is a tensile strained quantum well layer, and the first strained barrier layer is a compressive strained barrier layer;
the material of the tensile strained quantum well layer comprises GaAsₓ₃P₁₋ₓ₃;
the material of the compressive strained barrier layer comprises Inₓ₁Ga₁₋ₓ₁P; and
the material of the second barrier layer comprises Alₓ₂Ga₁₋ₓ₂As.

22. The method of claim 21 for manufacturing the high-efficiency active layer, wherein:
the strained quantum well layer is formed after the first strained barrier layer is formed;
in the step of forming the first strained barrier layer, an In-source gas, a Ga-source gas and a P-source gas are introduced;
in the step of forming the strained quantum well layer, the Ga-source gas, an As-source gas, and the P-source gas are introduced; between the step of forming the first strained barrier layer and the step of forming
the strained quantum well layer, first interruption processing, second interruption processing and third interruption processing are sequentially performed;
during the first interruption processing, the In-source gas, the Ga-source gas and the As-source gas are turned off, and the P-source gas is introduced;
during the second interruption processing, the In-source gas and the Ga-source gas are turned off, and the As-source gas and the P-source gas are introduced; and
during the third interruption processing, the In-source gas and the Ga-source gas are turned off, and the As-source gas and the P-source gas are introduced, wherein a supplying amount of the P-source gas decreases with time during the third interruption processing.

23. The method of claim 21 for manufacturing the high-efficiency active layer, wherein:
the second barrier layer is formed after the strained quantum well layer is formed;
in the step of forming the strained quantum well layer, the Ga-source gas, the As-source gas and the P-source gas are introduced;
in the step of forming the second barrier layer, an Al-source gas, the Ga-source gas and the As-source gas are introduced;
fourth interruption processing is performed between the step of forming the strained quantum well layer and the step of forming the second barrier layer; and
in the fourth interruption processing, the Ga-source gas and the P-source gas are turned off, and the As-source gas is introduced.

24. The method of claim 20 for manufacturing the high-efficiency active layer, wherein
aluminous wavelength of the high-efficiency active layer is in a range of 870 nm to 1100 nm; the strained quantum well layer is a compressive strained quantum well layer, and the first strained barrier layer is a tensile strained barrier layer; the material of the compressive strained quantum well layer comprises Inₓ₆Ga₁₋ₓ₆As; the material of the tensile strained barrier layer comprises GaAsₓ₄P₁₋ₓ₄; and the material of the second barrier layer comprises Alₓ₅Ga₁₋ₓ₅As.

25.-30. (canceled)
